(19) United States
(12) Patent Application Publication
(10) Pub. No.: US 2026/0073849 A1
(43) Pub. Date: Mar. 12, 2026

(54) DISPLAY PANEL AND DISPLAY DEVICE

(71) Applicant: Xiamen Tianma Display Technology Co., Ltd., Xiamen (CN)

(72) Inventors: Yongkang LI, Xiamen (CN); Qingjun LAI, Xiamen (CN)

(21) Appl. No.: 19/311,284

(22) Filed: Aug. 27, 2025

(30) Foreign Application Priority Data
Sep. 9, 2024 (CN) 202411259873.4

(51) Int. Cl. G09G 3/32; G11C 19/28

(52) U.S. Cl. CPC G09G 3/32; G11C 19/287; G09G 2300/0819; G09G 2300/0833; G09G 2300/0861; G09G 2310/0286; G09G 2310/04; G09G 2320/0233; G09G 2330/021; G09G 2340/0435

(57) ABSTRACT

Display panel and display device are provided. The display panel includes a driving circuit includes N-level shift registers connected in cascade with N≥2. A shift register of the N-level shift registers includes a first control part and a second control part. The first control part is electrically connected to the second control part. The first control part is configured to control a first output signal, and the first output signal of an i-th level shift register serves as an input signal of a j-th level shift register, where 1≤i≤N, and 1≤j≤N. The second control part includes a control unit and a first voltage stabilizing unit.

### CROSS-REFERENCE TO RELATED APPLICATION

This application claims priority of Chinese Patent Application No. 2024112598734, filed on Sep. 9, 2024, the entire contents of which are hereby incorporated by reference.

### FIELD OF THE DISCLOSURE

The present disclosure generally relates to the field of display technology and, more particularly, relates to a display panel and a display device.

### BACKGROUND

With the continuous development of display technology, electronic devices with display functions are increasingly used in people's daily life and work, providing significant convenience.

A key component of an electronic device that enables display functionality is a display panel. Current display panels support partitioning and frequency division, allowing different areas of a display to have varying refresh rates to reduce power consumption by reducing refresh frequencies of some areas. However, the partitioning and frequency division can lead to an issue of dark or bright lines at junctions between different areas, thereby affecting display uniformity.

### BRIEF SUMMARY OF THE DISCLOSURE

One aspect of the present disclosure provides a display panel. The display panel includes a driving circuit includes N-level shift registers connected in cascade with N≥2. A shift register of the N-level shift registers includes a first control part and a second control part. The first control part is electrically connected to the second control part. The first control part is configured to control a first output signal, and the first output signal of an i-th level shift register serves as an input signal of a j-th level shift register, where 1≤i≤N, and 1≤j≤N. The second control part includes a control unit and a first voltage stabilizing unit. The control unit at least receives a frequency control signal, a first voltage signal input from a first voltage input terminal and a second voltage signal input from a second voltage input terminal and controls a second output signal. A voltage corresponding to a valid pulse of the second output signal is same as a voltage of the first voltage signal, a voltage corresponding to an invalid pulse of the second output signal is same as a voltage of the second voltage signal. A first terminal of the first voltage stabilizing unit is electrically connected to the control unit, and a second terminal of the first voltage stabilizing unit receives a fixed voltage signal. A voltage signal line connected to the second terminal of the first voltage stabilizing unit is different from a voltage signal line connected to the first voltage input terminal.

Another aspect of the present disclosure provides a display device including a display panel. The display panel includes a driving circuit includes N-level shift registers connected in cascade with N≥2. A shift register of the N-level shift registers includes a first control part and a second control part. The first control part is electrically connected to the second control part. The first control part is configured to control a first output signal, and the first output signal of an i-th level shift register serves as an input signal of a j-th level shift register, where 1≤i≤N, and 1≤j≤N. The second control part includes a control unit and a first voltage stabilizing unit. The control unit at least receives a frequency control signal, a first voltage signal input from a first voltage input terminal and a second voltage signal input from a second voltage input terminal and controls a second output signal. A voltage corresponding to a valid pulse of the second output signal is same as a voltage of the first voltage signal, a voltage corresponding to an invalid pulse of the second output signal is same as a voltage of the second voltage signal. A first terminal of the first voltage stabilizing unit is electrically connected to the control unit, and a second terminal of the first voltage stabilizing unit receives a fixed voltage signal. A voltage signal line connected to the second terminal of the first voltage stabilizing unit is different from a voltage signal line connected to the first voltage input terminal.

Other aspects of the present disclosure can be understood by a person skilled in the art in light of the description, the claims, and accompanying drawings of the present disclosure.

### BRIEF DESCRIPTION OF THE DRAWINGS

FIG. 1 illustrates a schematic diagram of a display panel;

FIG. 2 illustrates a schematic diagram of a driving circuit in the display panel shown in FIG. 1;

FIG. 3 illustrates a schematic diagram of a pixel circuit in the display panel shown in FIG. 1;

FIG. 4 illustrates a schematic diagram of a gating circuit in the driving circuit shown in FIG. 2;

FIG. 5 illustrates a driving timing diagram of the driving circuit shown in FIG. 2;

FIG. 6 illustrates a driving timing diagram of the display panel shown in FIG. 1;

FIG. 7 illustrates a schematic diagram of a display panel consistent with various embodiments of the present disclosure;

FIG. 8 illustrates a schematic diagram of a driving circuit in the display panel shown in FIG. 7;

FIG. 9 illustrates a schematic diagram of a shift register in the driving circuit shown in FIG. 8;

FIG. 10 illustrates a driving timing diagram of shift registers at each stage in the driving circuit shown in FIG. 8;

FIG. 11 illustrates another schematic diagram of a shift register in the driving circuit shown in FIG. 8;

FIG. 12 illustrates another schematic diagram of a shift register in the driving circuit shown in FIG. 8;

FIG. 13 illustrates another schematic diagram of a shift register in the driving circuit shown in FIG. 8;

FIG. 14 illustrates another schematic diagram of a shift register in the driving circuit shown in FIG. 8;

FIG. 15 illustrates another schematic diagram of a shift register in the driving circuit shown in FIG. 8;

FIG. 16 illustrates another schematic diagram of a shift register in the driving circuit shown in FIG. 8;

FIG. 17 illustrates another schematic diagram of a shift register in the driving circuit shown in FIG. 8;

FIG. 18 illustrates another schematic diagram of a shift register in the driving circuit shown in FIG. 8;

FIG. 19 illustrates another schematic diagram of a shift register in the driving circuit shown in FIG. 8;

FIG. 20 illustrates another schematic diagram of a shift register in the driving circuit shown in FIG. 8;

FIG. 21 illustrates a driving timing diagram of a first control unit in the shift register shown in FIG. 20;

FIG. 22 illustrates a schematic diagram of a pixel circuit consistent with various embodiments of the present disclosure;

FIG. 23 illustrates a schematic diagram of another pixel circuit consistent with various embodiments of the present disclosure;

FIG. 24 illustrates a schematic diagram of another pixel circuit consistent with various embodiments of the present disclosure;

FIG. 25 illustrates a schematic diagram of another pixel circuit consistent with various embodiments of the present disclosure;

FIG. 26 illustrates a schematic diagram of another pixel circuit consistent with various embodiments of the present disclosure;

FIG. 27 illustrates a driving timing diagram of the display panel shown in FIG. 7;

FIG. 28 illustrates another driving timing diagram of the display panel shown in FIG. 7; and

FIG. 29 illustrates a schematic diagram of a display device consistent with various embodiments of the present disclosure.

### DETAILED DESCRIPTION

The present disclosure will be described in further detail below in conjunction with the accompanying drawings and embodiments. The specific embodiments described herein are intended to only explain rather than to limit the present disclosure. It should also be noted that, for ease of description, only the parts related to the present disclosure are shown in the accompanying drawings, rather than all structures.

Terminologies used in the embodiments of the present disclosure are only for the purpose of describing specific embodiments and are not intended to limit the present disclosure. It should be noted that directional terms such as “upper”, “lower”, “left” and “right” described in the embodiments of the present disclosure are based on perspectives shown in the accompanying drawings and should not be considered limiting to implementations of the present disclosure. Additionally in the context, it will be understood that when an element is formed “on” or “under” another element, it can be either directly “on” or “under” the element, or indirectly “on” or “below” another element through intervening elements. Terms “first”, “second”, and the like are used for descriptive purposes only and do not imply any order, quantity or importance, but are only used to distinguish different components. Specific meanings of the above terms in the present disclosure can be understood on a case-by-case basis by a person skilled in the art.

Term “include” and variations thereof in the present disclosure indicate open-ended inclusion, meaning “including but not limited to”. The term “based on” means “based at least in part on”, and “one embodiment” means “at least one embodiment”.

It should be noted that terms like “first” and “second” in the present disclosure are only used to distinguish corresponding elements and do not imply any specific order or interdependence.

It should be noted that the modifications of “one” and “a plurality of” in the present disclosure are illustrative and not restrictive. A person skilled in the art will understand that, unless the context clearly indicates otherwise, the terms should be interpreted as “one or a plurality of”.

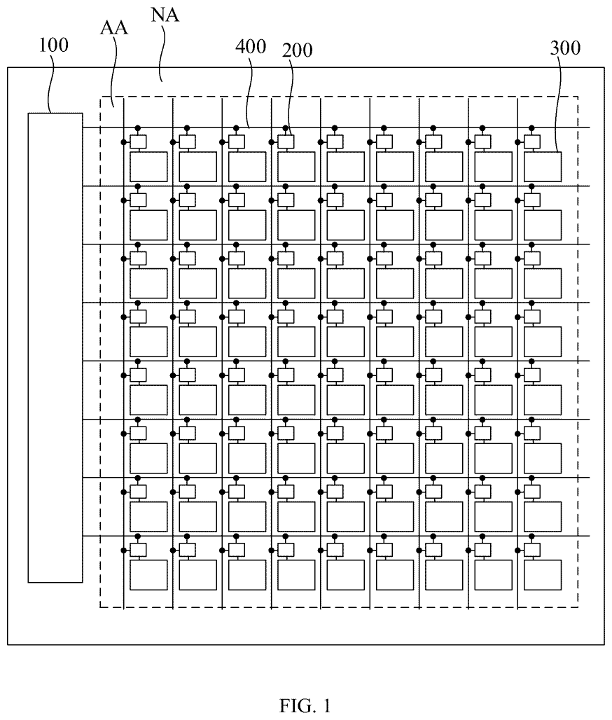

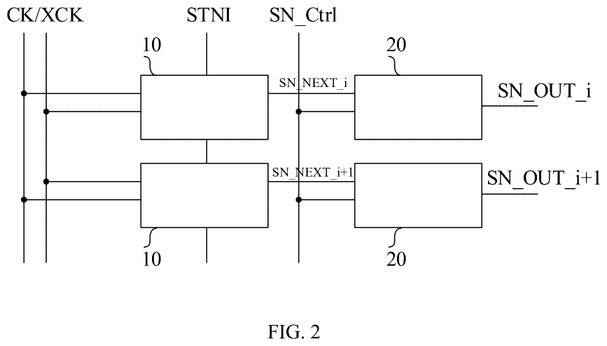

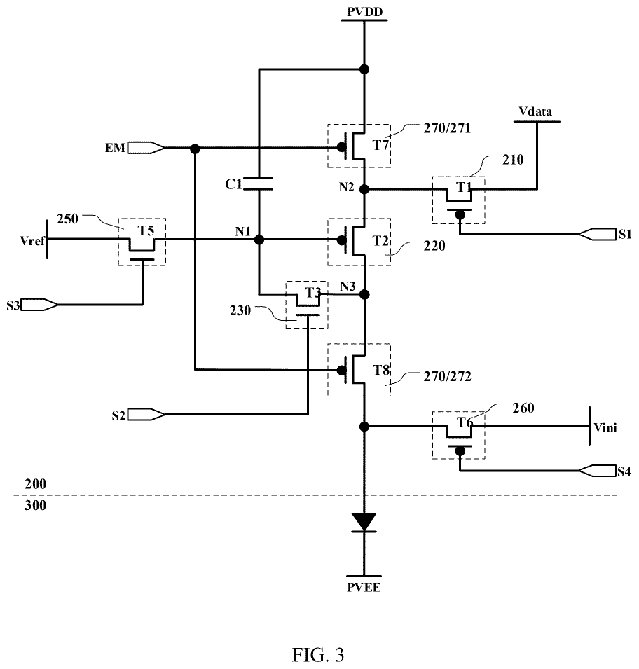

FIG. 1 illustrates a schematic diagram of a display panel. FIG. 2 illustrates a schematic diagram of a driving circuit in the display panel shown in FIG. 1. FIG. 3 illustrates a schematic diagram of a pixel circuit in the display panel shown in FIG. 1. Referring to FIGS. 1-3, in a related art, the display panel includes a display area AA and a non-display area NA. The non-display area NA is provided with a driving circuit 100, and the display area AA includes a plurality of pixel circuits 200 arranged in an array and light-emitting elements 300 electrically connected to the plurality of pixel circuits 200 in one-to-one correspondence. The driving circuit 100 sequentially provides driving signals to the pixel circuits 200 in each row through scan signal lines 400. A pixel circuit 200 of the plurality of pixel circuits 200 controls a corresponding electrically connected light-emitting element 300 to illuminate according to a driving signal. In a display frame, the light-emitting elements 300 in the display area AA are controlled to illuminate sequentially. By matching adjacent light-emitting elements 300 of different colors, specific pixels can be formed, enabling a comprehensive display of an entire image.

Referring to FIGS. 1-3, in a related art, the driving circuit 100 in the non-display area NA is arranged with multi-level shift register circuits 10 in cascade, with a gating circuit 20 arranged for each level of the shift register circuit 10. An output terminal of each stage of the gating circuit 20 is connected to at least one row of pixel circuits 200 through at least one scan signal line 400. A shift register circuit 10 is responsible for outputting a scan pulse signal SN_NEXT at each level. A gating circuit 20 is correspondingly connected to an output terminal of the shift register circuit 10 and is used for receiving the scan pulse signal SN_NEXT, and selectively outputting a scan pulse signal SN_NEXT under control of a control signal SN_Ctrl. Therefore, an output frequency of the scan pulse signal SN_NEXT can be controlled through the control signal SN_Ctrl to adjust a refresh frequency of a corresponding connected pixel row, which allows different partitions of the display panel to have varying refresh frequencies, enabling a partition frequency adjustment function to adapt to the power consumption requirements of different display scenarios.

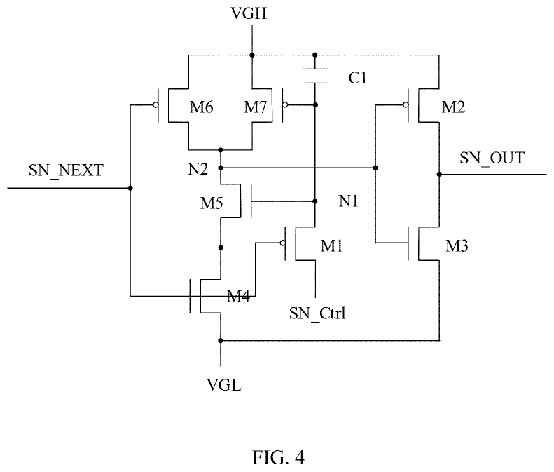

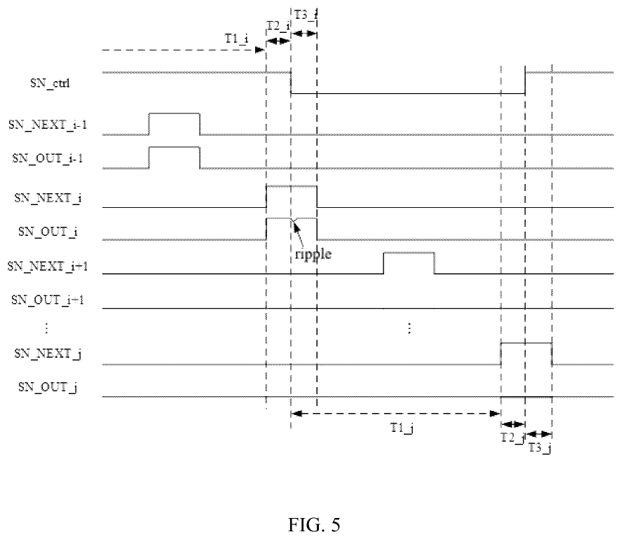

FIG. 4 illustrates a schematic diagram of a gating circuit in the driving circuit shown in FIG. 2. FIG. 5 illustrates a driving timing diagram of the driving circuit shown in FIG. 2. Referring to FIGS. 1-5, in a related art, a capacitor C1 is arranged in a gating circuit 20. Two terminals of the first capacitor C1 are connected to a first node N1 and a VGH signal line respectively. Remaining circuit components and connections thereof will not be described in detail but can be referenced in FIG. 4.

Referring to a signal timing of an i-th level shift register circuit in FIG. 5, in a first stage T1_i, a SN_NEXT_i signal is at a low level, a P-channel transistor M1 is turned on, and a SN_Ctrl signal is at a high level, which charges the first capacitor C1, and raises a voltage at the first node N1 to a high level. In a second stage T2_i, that is, when the SN_NEXT_i signal transitions from low to high, N-channel transistors M4 and M5 are turned on, and a VGL signal is charged into the second node N2 by the transistors M4 and M5, so that a P-channel transistor M2 is turned on, a N-channel transistor M3 is turned off, and a VGH signal is output through a transistor M2 to form a SN_OUT signal. That is, in the second stage T2_i, when the SN_NEXT signal transitions from low to high, the SN_OUT signal also transitions from low to high. In a third stage T3_i, that is, when both the SN_NEXT and SN_OUT signals are at a high level, and SN_Ctrl transitions from high to low, because a transistor M1 is turned off by the SN_NEXT signal, the SN_Ctrl signal cannot be written to the first node N1. Since the first capacitor C1 remains connected and maintained at a high level, the SN_OUT signal is not interrupted and can still be output as a complete valid pulse.

Similarly, referring to a signal timing of an j-th level shift register circuit in FIG. 5, in a first stage T1_j, when a SN_Ctrl_j signal and the SN_NEXT_j signal are both at low-levels, the P-type channel transistor M1 is turned on, charging the first capacitor C1 and bringing the first node N1 to a low level. The N-type channel transistor M5 is turned off, the P-type channel transistor M7 is turned on, allowing the VGH signal to charge into the second node N2 via transistor M7, causing the P-type channel transistor M2 to turn off, and the N-type channel transistor M3 to turn on, resulting in the SN_OUT_j outputting the VGL signal through the transistor M3. In a second stage T2_j, that is, after the SN_NEXT_j signal transitions from low to high, the transistor M1 is turned off, preventing the SN_Ctrl_j signal from being written to the first node N1. Regardless of the state of the SN_Ctrl signal, the voltage at the first node N1 remains affected by the first capacitor C1, allowing the second node N2 to maintain a high level. As a result, SN_OUT_j outputs the VGL signal through transistor M3. In a third stage T3_j, when the SN_Ctrl_j signal transitions from low to high, the SN_OUT_j signal still outputs the VGL signal through the transistor M3.

From the above, in a related art, when a gating circuit 20 is designed to use the SN_Ctrl signal to control an output of the SN_NEXT signal, the first capacitor C1 is used to maintain a voltage of the first node N1 to prevent the SN_Ctrl signal from being cut off when the SN_Ctrl signal transitions from high to low or from low to high, ensuring that SN_OUT outputs a complete pulse signal.

However, as shown in the structure and working principle of the drive circuit above, one terminal of the first capacitor C1 is connected to the first node N1 of the drive circuit 100 for stabilizing the voltage of the first node N1, and the other terminal of the first capacitor C1 is connected to the VGH signal line, which stabilizes the voltage of the first node N1 using a fixed voltage signal to prevent interference from other signals, thereby avoiding fluctuations in the voltage of the first node N1. However, when the SN_Ctrl signal transitions from high to low or from low to high, the SN_Ctrl signal affects a switching state of transistor M1, causing fluctuations in the voltage of the first node N1, which in turn causes the VGH signal to fluctuate through the first capacitor C1, as shown in FIG. 5, resulting in an i-th level output signal SN_OUT_i to generate a ripple with a same transition characteristics as the SN_Ctrl signal during a process of outputting a complete high-level pulse.

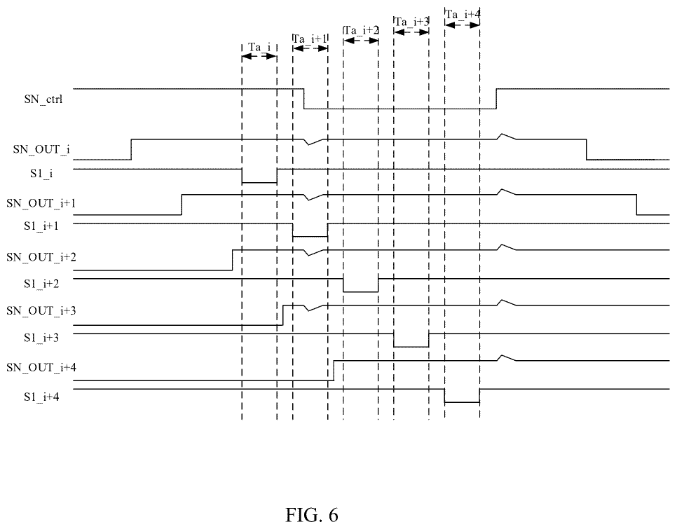

FIG. 6 illustrates a driving timing diagram of the display panel shown in FIG. 1. Referring to FIGS. 3, 5 and 6, it should be noted that pulse width ratios of the control signal SN_Ctrl, the output signal SN_OUT, and a first scan signal S1 in FIG. 6 are provided as examples and may differ from actual conditions. The deviations between the pulse width ratios of the control signal SN_Ctrl, the output signal SN_OUT, and the first scan signal S1 in FIG. 6 and pulse width ratios that might occur in actual practice or implementation are not considered limitations. For a pixel circuit 200 in any row, a gate of a specific transistor can receive the output signal SN_OUT of a corresponding driving circuit 100. That is, the output signal SN_OUT of the driving circuit 100 controls a switching of a specific transistor, thereby regulating an operation of the pixel circuit 200. Taking a gate of the N-type channel transistor T5 in an i-th row of pixel circuit 200 as an example, the gate of the transistor T5 receives the output signal SN_OUT in the i-th level driving circuit 100, that is, a first scan signal S1_i received by the transistor T5 in the i-th row pixel circuit 200 is the output signal SN_OUT of the i-th level driving circuit 100. In a data writing stage Ta_i of the i-th level pixel circuit 200, the first scan signal S1_i inputs a valid pulse to the gate of the transistor T1 to control the transistor T1 to turn on. When the output signal SN_OUT_i of the i-th level driving circuit 100 is in a high level stage, that is, in an effective level stage of the N-channel transistor T3, the transistor T3 is turned on, and a data signal Vdata is written to the first node N1 of the pixel circuit 200 through the transistor T1, the transistor T2, and the transistor T3 in sequence.

However, ripples may occur in a high-level pulse of the output signal SN_OUT from a certain level of the driving circuit 100, potentially affecting a turning-on state of the transistor T3. When the ripples happen to be in a low-level pulse stage of the first scan signal S1 of the pixel circuit 200 of a corresponding row, that is, in a data writing stage Ta of the pixel circuit 200, the ripples will interfere with a data writing process of the pixel circuit 200, so that a voltage written in the first node N1 of the pixel circuit 200 is higher or lower. A row of pixel circuits 200 driven by the driving circuit 100 may appear darker or brighter in relation to the electrically connected light-emitting elements 300, leading to visible rows of dark or bright lines. As shown in FIG. 6 for pixels in an (i+1)-th row, a ripple occurs in a low-level pulse stage of a first scan signal S1_(i+1) of a pixel circuit 200 in the (i+1)-th row, that is, the ripple present in a data writing stage Ta_(i+1) of the pixel circuit 200 in the (i+1)-th row. A turning-on state of the transistor T3 will be affected by the ripple, which will interfere with the data writing process of the pixel circuit 200, causing the first node N1 of the pixel circuit 200 in the (i+1)-th row to accumulate more charge and voltage. As a result, a row of pixel circuits 200 driven by the driving circuit 100 corresponding to the electrically connected light-emitting elements 300 becomes darker and appears as a row of dark lines. The ripple is caused by high and low level transitions of the SN_Ctrl signal in the driving circuit 100. The SN_Ctrl signal is a control signal for determining whether the driving circuit 100 outputs a valid SN_OUT pulse to the pixel circuit 200. That is, the level transition of the SN_Ctrl signal indicates that a current level gating circuit 20 is controlling a pixel circuit 200 in a corresponding row to change the refresh frequency. Therefore, the ripple will correspond to a period during which a display is driven in an interface area between two partitions with different refresh frequencies. Therefore, a presence of the first capacitor C1 in the driving circuit 100 will cause valid pulses in the output signal SN_OUT to generate ripples, which will lead to the display panel with partition frequency adjustment function to produce dark lines or bright lines in the interface areas between different partitions, resulting in abnormal display issues that seriously affect an overall display quality.

To address the technical problems outlined above, one embodiment provides a display panel that includes a driving circuit. The driving circuit consists of N-level shift registers connected in cascade, where N≥2. Each shift register includes a first control part and a second control part. The first control part is electrically connected to the second control part. The first control part is configured for controlling a first output signal. The first output signal of an i-th level shift register serves as an input signal of a j-th level shift register, where 1≤i≤N, and 1≤j≤N.

The second control part includes a control unit and a first voltage stabilizing unit. The control unit receives a frequency control signal, a first voltage signal input from a first voltage input terminal and a second voltage signal input from a second voltage input terminal to control a second output signal. A voltage corresponding to a valid pulse of the second output signal is same as a voltage of the first voltage signal. A voltage corresponding to an invalid pulse of the second output signal is same as a voltage of the second voltage signal. A first terminal of the first voltage stabilizing unit is electrically connected to a control unit, and a second terminal of the first voltage stabilizing unit receives a fixed voltage signal. The second terminal of the first voltage stabilizing unit is connected to the first voltage input terminal with different voltage signal lines.

In the above technical solution, by arranging the first control part and the second control part in the shift register, the first control part controls a first output signal, so that the first output signal of the i-th level shift register is an input signal of the j-th level shift register, thereby realizing a cascading of at least two levels of the first control part. The control unit is configured to receive at least the frequency control signal, the first voltage signal input from the first voltage input terminal and the second voltage signal input from the second voltage input terminal to control the second output signal. As a result, a voltage corresponding to a valid pulse of the second output signal is same as the voltage of the first voltage signal, and a voltage corresponding to an invalid pulse of the second output signal matches the voltage of the second voltage signal. The frequency control signal can be used to realize a conversion of a valid pulse and an invalid pulse of the second output signal, thereby controlling the pixel circuit and adjusting refresh frequencies of different areas of the display panel. In addition, the first terminal of the first voltage stabilizing unit is electrically connected to the control unit, and the second terminal of the first voltage stabilizing unit receives a fixed voltage signal and is connected to a different voltage signal line with the first voltage input terminal. The first voltage stabilizing unit can stabilize a voltage of the control unit connected to the first voltage stabilizing unit and maintain an operational state of the control unit, which prevents the second output signal of the control unit from being cut off in a valid pulse stage and ensuring the output of a complete valid pulse. Maintaining an operational state of the control unit also prevents the second terminal of the first voltage stabilizing unit from interfering with the first voltage signal at the first voltage input terminal, which, in turn, prevents fluctuations in the second output signal during valid pulse output, avoiding disruptions to the pixel circuit's operation. As a result, corresponding light-emitting elements of the pixel circuit can emit light at a target brightness, thereby avoiding display issues such as bright or dark lines and ensuring display quality.

The above is a core idea of the present disclosure. The technical solutions in the embodiments of the present disclosure will be clearly and completely described below with reference to the accompanying drawings in the embodiments of the present disclosure. Based on the embodiments of the present disclosure, all other embodiments obtained by a person skilled in the art without creative efforts fall within the protection scope of the present disclosure.

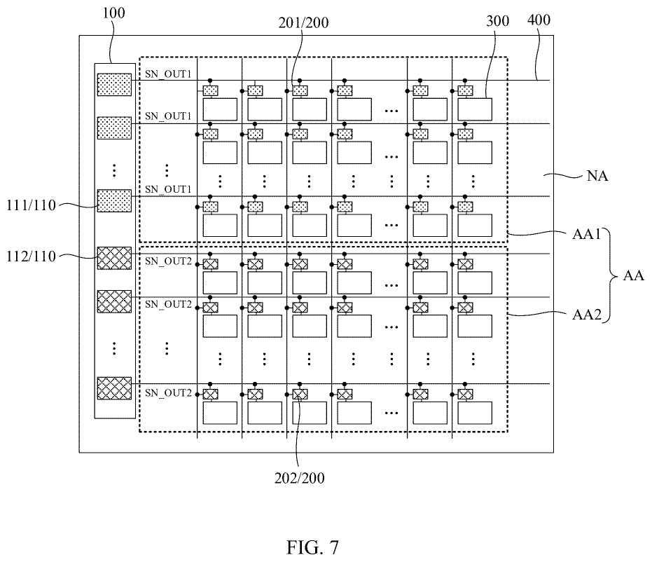

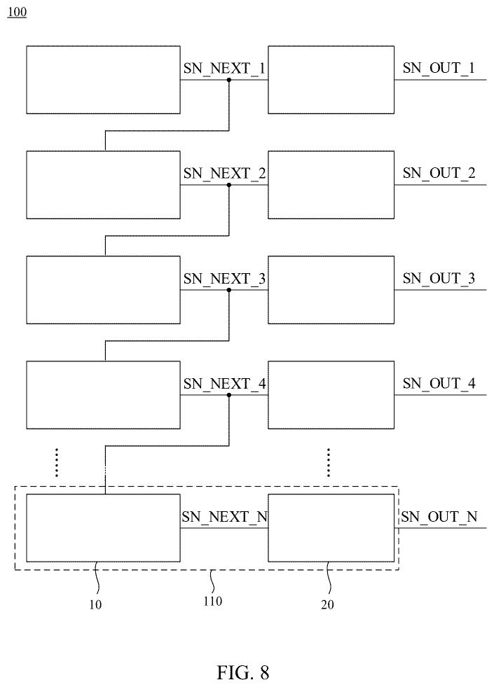

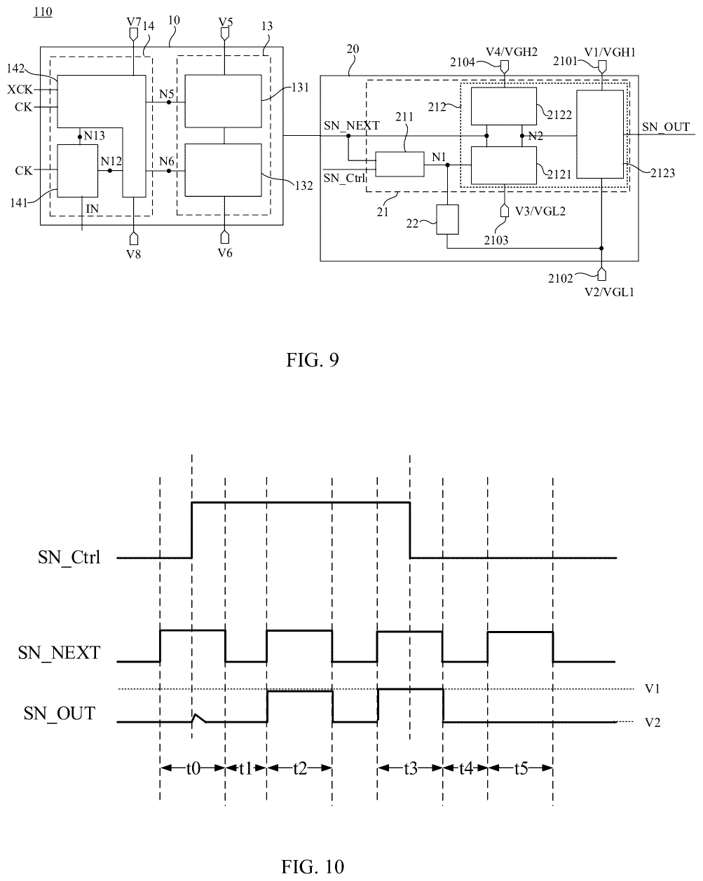

FIG. 7 illustrates a schematic diagram of a display panel consistent with various embodiments of the present disclosure. FIG. 8 illustrates a schematic diagram of a driving circuit in the display panel shown in FIG. 7. FIG. 9 illustrates a schematic diagram of a shift register in the driving circuit shown in FIG. 8. FIG. 10 illustrates a driving timing diagram of shift registers at each stage in the driving circuit shown in FIG. 8. Referring to FIGS. 7-10, the display panel includes a driving circuit 100, which consists of N-level shift registers 110 cascaded with each other, where N≥2. Each shift register 110 includes a first control part 10 and a second control part 20, which are electrically connected. The first control part 10 controls the first output signal SN_NEXT of the i-th level shift register 110, which serves as the input signal for the j-th level shift register 110, where 1≤i≤N and 1≤j≤N.

The second control part 20 includes a control unit 21 and a first voltage stabilizing unit 22, The control unit 21 receives at least one frequency control signal SN_Ctrl, a first voltage signal V1 input by a first voltage input terminal 2101, and the first voltage signal V1 input by a second voltage input terminal 2102. A second voltage signal V2 controls the second output signal SN_OUT. A voltage corresponding to a valid pulse of the second output signal SN_OUT is same as a voltage of the first voltage signal V1, and a voltage corresponding to an invalid pulse of the second output signal SN_OUT is same as a voltage of the second voltage signal V2. A first terminal of the first voltage stabilizing unit 22 is electrically connected to the control unit 21, and a second terminal of the first voltage stabilizing unit 22 receives a fixed voltage signal. A voltage signal line connected to the second terminal of the first voltage stabilizing unit 22 is different from a voltage signal line connected to the first voltage input terminal 2101.

As shown in FIGS. 8 and 9, at least two levels of shift registers 110 are arranged in the driving circuit 100 of the display panel. The at least two level shift registers 110 form a cascade, meaning that an output signal of a shift register 110 serves as an input signal of a shift register 110 in a subsequent level. For example, an output signal of a preceding adjacent shift register 110 serves as an input signal for a next-level shift register 110. In the embodiment, the shift register 110 consists of the first control part 10 and the second control part 20. The first control part 10 in each level shift register 110 actually forms the aforementioned cascade relationship, that is, the first output signal SN_NEXT of a shift register 110 output by the first control unit 10 in the register 110 serves as an input signal of a first control unit 10 in a shift register 110 in a subsequent level. For the second control part 20 in each level shift register 110, as illustrated in the embodiments of FIG. 8 and FIG. 9, the output terminal of the first control part 10, which outputs the first output signal SN_NEXT is electrically connected to the second control part 20. That is, the first output signal SN_NEXT provided by the first control part 10 servers as a control signal of the second control part 20 and is simultaneously controlled by an additionally input frequency control signal SN_Ctrl to realize an output of the second output signal SN_OUT. In addition, a first voltage input terminal 2101 and a second voltage input terminal 2102 are arranged in the second control part 20. A voltage corresponding to a valid pulse of the second output signal SN_OUT is same as a voltage of the first voltage signal V1. A voltage corresponding to an invalid pulse of the second output signal SN_OUT is same as the voltage of the second voltage signal V2. Essentially, through a frequency control signal SN_Ctrl, an operational state of the second control part 20 is synchronously controlled, and the first voltage signal V1 and the second voltage signal V2 are output in different time periods, thereby constituting two different level pulses of the second output signal SN_OUT, namely valid pulses and invalid pulses. A valid pulse refers to a level pulse that can drive connected circuit structures, components, or the like to turn on. An invalid pulse refers to a level pulse that can drive connected circuit structures, components, or the like to turn off. For the second output signal SN_OUT, a valid pulse refers to a level pulse that can turn on a component in a corresponding connected pixel circuit, while an invalid pulse refers to a level pulse that can turn off the component in the corresponding connected pixel circuit. There is a relative concept between levels of a valid pulse and an invalid pulse. The second output signal SN_OUT can represent a valid pulse as a high-level pulse and an invalid pulse as a low-level pulse. As shown in FIG. 10, the first voltage V1 is a high-level signal, the second voltage V2 is a low-level signal. Alternatively, the second output signal SN_OUT can also have a valid pulse as a low-level pulse, and an invalid pulse as a high-level pulse, with the first voltage V1 being a low-level signal, and the second voltage V2 being a high-level signal.

In addition, in the embodiment, the control unit 21 and the first voltage stabilizing unit 22 are arranged in the second control part 20. The control unit 21 is responsible for receiving the control of the frequency control signal SN_Ctrl and outputting the second output signal SN_OUT. The first voltage stabilizing unit 22 is responsible for regulating a output process of the control unit 21 to ensure a stable output of the control unit 21. Specifically, the first terminal of the first voltage stabilizing unit 22 is connected to the control unit 21 and the second terminal of the first voltage stabilizing unit 22 is connected to a fixed voltage signal. Based on the fixed voltage of the second terminal, a connection node in the control unit 21 is stabilized to maintain a operational state of the control unit 21. Moreover, in the embodiment, the voltage signal line connected to the second terminal of the first voltage stabilizing unit 22 is different from the voltage signal line connected to the first voltage input terminal 2101. The second terminal of the first voltage stabilizing unit 22 and the first voltage input terminal 2101 can be understood as two nodes or terminal points in the circuit of the second control unit 20 within each level shift register 110, which receive controls from external voltage signals. The two nodes or terminal points respectively receive corresponding external voltage signals through different voltage signal lines. The two voltage signal lines extend within the display panel to connect the two nodes or terminal points in each level shift register 110, and also extend to a bonding area where the display panel connects to external components and are linked to bonding terminals in the bonding area. The voltage signals transmitted through the two voltage signal lines may be either different or identical. For example, when the two voltage signal lines are connected to different binding terminals, the two voltage signal lines receive different external voltage signals; or when two voltage signal lines are connected to different binding terminals, the two voltage signal lines receive a same external voltage signal; or when two voltage signal lines are connected to different binding terminals, the two voltage signal lines receive a same external voltage signal. Because the voltage signal lines connected to the second terminal of the first voltage stabilizing unit 22 and the first voltage input terminal 2101 are different, when the voltage of the second terminal of the first voltage stabilizing unit 22 changes, an impact on a voltage of the first voltage input terminal 2101 can be significantly reduced or even completely avoided. Therefore, when the control unit 21 outputs a valid pulse, the control unit 21 essentially outputs the first voltage signal V1 input from the first voltage input terminal 2101 at a specific time to form a valid pulse, and the second terminal of the first voltage stabilizing unit 22 and the first voltage input terminal 2101 are connected to different voltage signal lines. Therefore, the voltage stabilization process of the first voltage stabilizing unit 22 will not cause interference to the first voltage signal V1 input by the first voltage input terminal 2101. That is, when the second output signal SN_OUT is in the valid pulse stage, its pulse will not be affected by the first voltage signal V1. The influence of the voltage stabilizing unit 22 can avoid ripples in valid pulses of the second output signal SN_OUT, thereby preventing interference with a data writing process of the pixel circuit and solving an issue where a display panel with partition frequency adjustment function produces dark lines or bright lines in junction areas of different partitions, ensuring normal display.

As mentioned above in FIGS. 8 and 9, in one embodiment, the output terminal of the first control part 10 that outputs the first output signal SN_NEXT is electrically connected to the second control part 20, that is, the first output signal SN_NEXT provided by the first control part 10 is simultaneously used as a control signal of second control unit 20. In other embodiments, the first control part 10 and the second control part 20 can adopt any other connection. For example, the second control part 20 is connected to a specific node in the first control part 10. A person skilled in the art can make selections and designs according to actual needs, which is not limited herein. Any reasonable modifications based on the present disclosure fall within the protection scope of the present disclosure.

As shown in FIG. 9, optionally, in one embodiment, the second terminal of the first voltage stabilizing unit 22 is electrically connected to the second voltage input terminal 2102.

The second terminal of the first voltage stabilizing unit 22 is electrically connected to the second voltage input terminal 2102. It can be understood that the two nodes or terminal points are either directly connected to a same voltage signal line or connected to different voltage signal lines. However, two voltage signal lines are connected to a same bonding terminal, or the two nodes or terminal points are directly electrically connected through a connecting line. In the embodiment, the second terminal of the first voltage stabilizing unit 22 is electrically connected to the second voltage input terminal 2102. Even if the frequency control signal SN_Ctrl is pulled down from a high level or pulled up from a low level, the control unit 21 affects the first voltage stabilizing unit 22 and only influences the second voltage input terminal 2102 through the first voltage stabilizing unit 22. Since when the control unit 21 outputs an invalid pulse, the control unit 21 essentially outputs the second voltage signal V2, which is input from the second voltage input terminal 2102 at a specific time to form an invalid pulse. Therefore, a transition of the frequency control signal SN_Ctrl will only cause the second output signal SN_OUT to produce ripples in an invalid pulse stage. Because the second output signal SN_OUT in the invalid pulse stage cannot activate corresponding connected components in the pixel circuit, the ripples in the second output signal SN_OUT has no impact on a normal operation of the pixel circuit. In summary, on the basis of stabilizing the voltage of the control unit 21 and maintaining a operational state of the control unit 21, the first voltage stabilizing unit 22 connects the second terminal thereof to the second voltage input terminal 2102 without interfering with the pixel circuit's operation and solves the issue of dark or bright lines in junctions of different partitions in a display panel with a partition frequency adjustment function, which can result in abnormal displays. In addition, since the second terminal of the first voltage stabilizing unit 22 is connected to the second voltage input terminal 2102 and stabilize a voltage through the second voltage input terminal 2102, a shift register circuit can avoid a need for additional fixed voltage signal lines for the first voltage stabilizing unit 22, which minimize the signal lines needed in a shift register circuit, supports the display panel in achieving a narrow frame and simplifies a structure and design of external drive devices and flexible circuit boards.

Optionally, in one embodiment, the second terminal of the first voltage stabilizing unit is electrically insulated from the second voltage input terminal. In the embodiment, the second terminal of the first voltage stabilizing unit is electrically insulated from the second voltage input terminal. It can be understood that the second terminal of the first voltage stabilizing unit, and the second voltage input terminal are connected to different voltage signal lines, which extend to a binding area of the display panel and connect to different binding terminals, thereby realizing that the signals between the two nodes or terminal points do not interfere with each other.

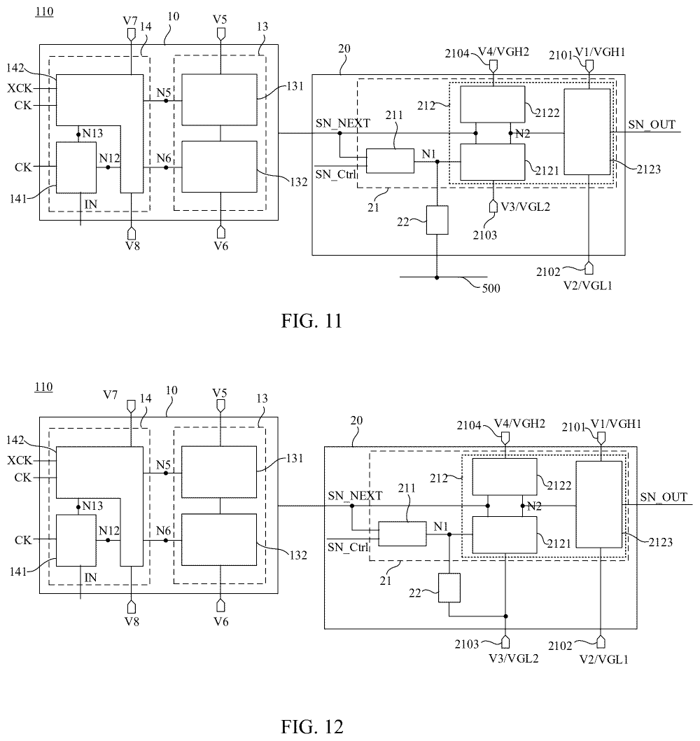

FIG. 11 illustrates another schematic diagram of a shift register in the driving circuit shown in FIG. 8. Referring to FIG. 11, in one embodiment, the display panel further includes a fixed voltage signal line 500 electrically connected to the second terminal of the first voltage stabilizing unit 22 in the shift register 110.

Therefore, in the embodiment, since the second terminal of the first voltage stabilizing unit 22 is electrically connected to the fixed voltage signal line 500, the first voltage stabilizing unit 22 maintains a stability of the second terminal through a fixed voltage provided by the fixed voltage signal line 500. On the one hand, the first voltage stabilizing unit 22 can stabilize the voltage of the control unit 21 and maintain an operational state of the control unit 21. On the other hand, interference from the first voltage stabilizing unit 22 with the first voltage V1 provided by the first voltage input terminal 2101 and the second voltage V2 provided by the second voltage input terminal 2102 can be avoided, which avoids fluctuations of valid pulses and invalid pulses in the second output signal SN_OUT, minimizes interference with the data writing in the pixel circuit and solves an issue of dark or bright lines in junctions of different partitions in the display panel with the partition frequency adjustment function, which can result in abnormal displays.

Optionally, one of the first voltage signal V1 and the second voltage signal V2 is a high-level signal, while the other is a low-level signal. a voltage value V0 of a fixed voltage signal satisfies: VGL≤V0≤VGH. VGH is a voltage value of the high-level signal between the first voltage signal and the second voltage signal, and VGL is a voltage value of the low-level signal between the first voltage signal and the second voltage signal.

In one embodiment, the fixed voltage signal on the fixed voltage signal line 500 and the first voltage V1 provided to the first voltage input terminal 2101 and the second voltage V2 provided to the second voltage input terminal 2102 are generally driven by an external driving device such as a motherboard through a flexible circuit board or the like. In other words, the driving motherboard can provide the fixed voltage signal V0, the high-level signal VGH and the low-level signal VGL to the shift register through the flexible circuit board. In the embodiment, the fixed voltage signal V0 is set within the range of the high-level signal VGH and the low-level VGL, which allows a simple voltage dividing circuit design to convert the high-level signal VGH and the low-level VGL into fixed voltage signals provided to the fixed voltage signal line 500. The above design simplifies a complexity of a corresponding external driving device and a flexible circuit board and prevents the voltage of the fixed voltage signal on the fixed voltage signal line 500 from being too high or too low, which may otherwise lead to excessive chip power consumption.

It can be understood that the fixed voltage signal line 500, which is connected to the second terminal of the first voltage stabilizing unit 22, may be different from a voltage signal line connected to the first voltage input terminal 2101 and a voltage signal line connected to the second voltage input terminal 2102. The above distinction helps avoid interference from the first voltage stabilizing unit 22 on the first voltage V1 provided by the first voltage input terminal 2101 and the second voltage V2 provided by the second voltage input terminal 2102.

FIG. 12 illustrates another schematic diagram of a shift register in the driving circuit shown in FIG. 8. FIG. 13 illustrates another schematic diagram of a shift register in the driving circuit shown in FIG. 8. Referring to FIG. 9 and FIG. 11 to FIG. 13, in one embodiment, the control unit 21 may include a first control unit 211 and a second control unit 212. The first control unit 211 receives at least the first output signal SN_NEXT and the frequency control signal SN_Ctrl and control a signal from the first node N1. The first terminal of the first voltage stabilizing unit 22 is electrically connected to the first node N1. The second control unit 212 receives at least the signal from the first node N1, the first voltage signal V1 of the first voltage input terminal 2101 and the second voltage signal V2 of the second voltage input terminal 2102 and controls the second output signal SN_OUT.

The first control unit 211 essentially controls the signal from the first node N1 based on the first output signal SN_NEXT and the frequency control signal SN_Ctrl, while the second control unit 212 essentially outputs the first voltage signal V1 and the second voltage signal V2 in different periods according to the signal from the first node N1, and form corresponding valid and invalid pulses of the second output signal SN_OUT. Therefore, the first node N1 in the control unit 21 is a key node for controlling the second output signal SN_OUT. Therefore, in one embodiment, the first terminal of the first voltage stabilizing unit 22 is electrically connected to the first node N1. The voltage of the first node N1 can be stabilized by the first voltage stabilizing unit 22, ensuring that the second output signal SN_OUT maintains valid or invalid pulses within a required period. For example, when the frequency control signal SN_Ctrl jumps, an integrity of the valid and invalid pulses is maintained, so that the second output signal SN_OUT can still output same complete valid pulses or invalid pulses as the first output signal SN_NEXT.

Referring to FIGS. 9 and 11-13, specifically, the second control unit 212 includes a first module 2121, a second module 2122 and a third module 2123. The first module 2121 receives the first output signal SN_NEXT, a signal from the first node N1 and the third voltage signal V3 from a third voltage input terminal 2103 and controls a signal from the second node N2. The second module 2122 receives the first output signal SN_NEXT, a signal from the first node N1 and the fourth voltage signal V4 of a fourth voltage input terminal 2104 and controls a signal from the second node N2. The third module 2123 receives the first voltage signal V1 of the first voltage input terminal 2101 and the second voltage signal V2 of the second voltage input terminal 2102, as well as at least signals from the second node N2, and outputs the second output signal SN_OUT. One of the third voltage signal V3 and the fourth voltage signal V4 is a high-level signal, while the other is a low-level signal.

Further, referring to FIGS. 12 and 13, the high-level signal from the first voltage signal V1 and the second voltage signal V2 differ in voltage from the high-level signal in the third voltage signal V3 and the fourth voltage signal V4. Similarly, the low-level signal from the first voltage signal V1 and the second voltage signal V2 differ in voltage from the low-level signal from the third voltage signal V3 and the fourth voltage signal V4.

The second terminal of the first voltage stabilizing unit 22 is electrically connected to the third voltage input terminal 2103 or the fourth voltage input terminal 2104. As shown in FIG. 12, the second terminal of the first voltage stabilizing unit 22 is electrically connected to the third voltage input terminal 2103. As shown in FIG. 13, the second terminal of the first voltage stabilizing unit 22 is electrically connected to the fourth voltage input terminal 2104.

The high-level signal from the first voltage signal V1 and the second voltage signal V2 differ in voltage from the high-level signal from the third voltage signal V3 and the fourth voltage signal V4. The low-level signal from the first voltage signal V1 and the second voltage signal V2 differ in voltage from the low-level signal from the third voltage signal V3 and the fourth voltage signal V4, indicating that the third voltage input terminal 2103 and the third voltage input terminal 2103 are at different voltages. That is, the third voltage input terminal 2103 and the fourth voltage input terminal 2104 are electrically insulated from the first voltage input terminal 2101 and the second voltage input terminal 2102 respectively. The voltages of the third voltage input terminal 2103 and the fourth voltage input terminal 2104 will not affect the voltages of the first voltage input terminal 2101 and the second voltage input terminal 2102. Similarly, in the above two embodiments, since the second terminal of the first voltage stabilizing unit 22 is electrically connected to either the third voltage input terminal 2103 or the fourth voltage input terminal 2104, the first voltage stabilizing unit 22 can, on one hand, stabilize the voltage of the control unit 21 through the third voltage signal V3 or the fourth voltage signal V4 and maintain an operational state of the first voltage stabilizing unit 22. On the other hand, interference from the first voltage stabilizing unit 22 on the first voltage V1 provided by the first voltage input terminal 2101 and the second voltage V2 provided by the second voltage input terminal 2102 can be avoided, which prevents valid and invalid pulses in the second output signal SN_OUT from fluctuating, avoids interference with a data writing of the pixel circuit, solves an issue where a display panel with partition frequency adjustment function produces dark lines or bright lines in junction areas of different partitions, thereby ensuring normal display.

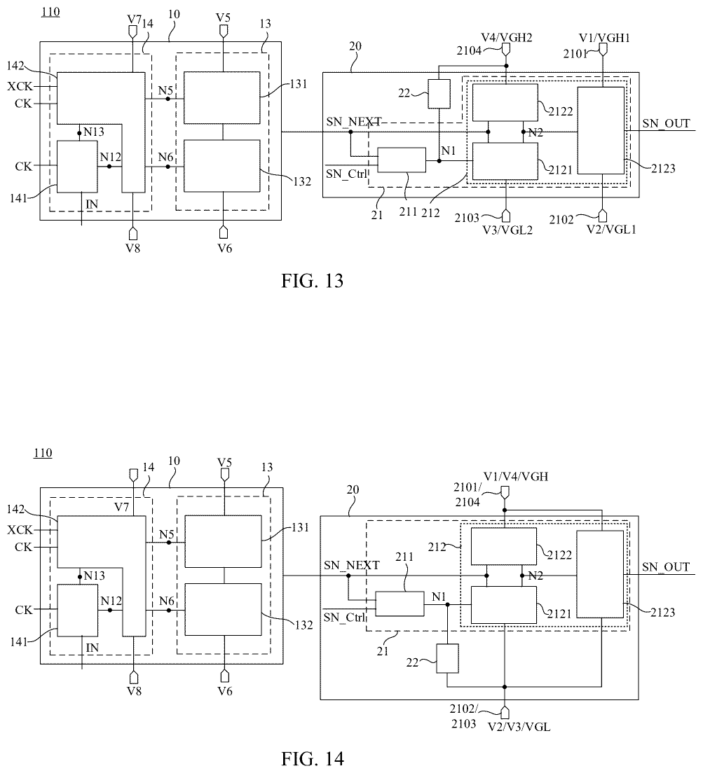

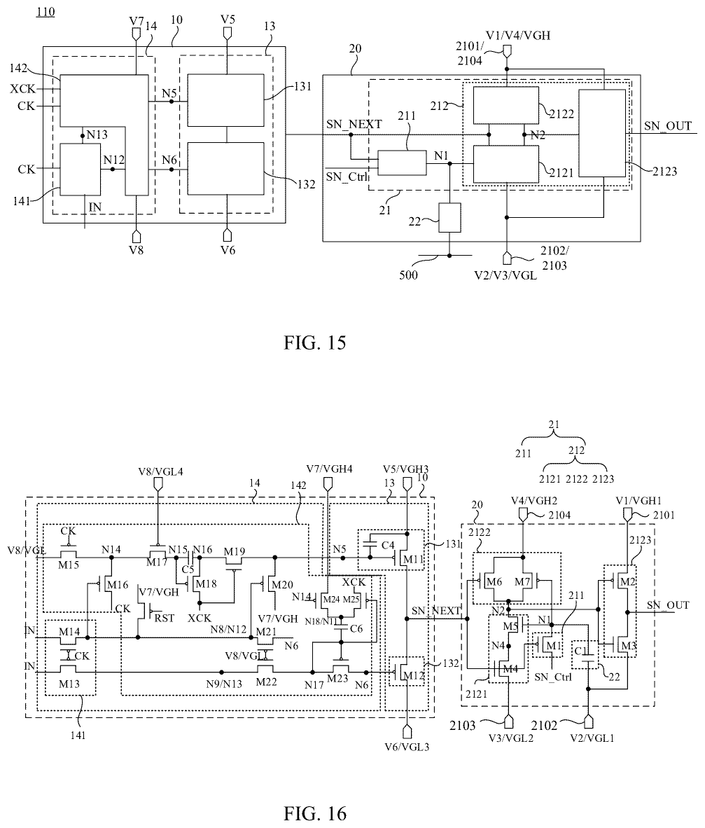

FIG. 14 and FIG. 15 illustrate two additional schematic diagrams of a shift register in the driving circuit shown in FIG. 8. Referring to FIGS. 14 and 15, in other embodiments, the high-level signal from the first voltage signal V1 and the second voltage signal V2 share a same voltage with the high-level signal from the third voltage signal V3 and the fourth voltage signal V4. Similarly, the low-level signal from the first voltage signal V1 and the second voltage signal V2 share a same voltage with the low-level signal from the third voltage signal V3, and the fourth voltage signal V4.

As described in the embodiments of FIGS. 14 and 15, the first voltage signal V1 in the first voltage signal and second voltage signal is a high-level signal, while the second voltage signal V2 is a low-level signal. Similarly, in a third voltage signal and a fourth voltage signal, the third voltage signal V3 is a low-level signal, and the fourth voltage signal V4 is a high-level signal. In one embodiment, the high-level signal from the first voltage signal V1 and the second voltage signal V2 share a same voltage with the high-level signal from the third voltage signal V3 and the fourth voltage signal V4, which means V1=V4=VGH. The low-level signal from the first voltage signal V1 and the second voltage signal V2 share a same voltage with the low-level signal from the third voltage signal V3 and the fourth voltage signal V4, which means V2=V3=VGL. Therefore, the first voltage input terminal 2101 and the fourth voltage input terminal 2104 can receive high-level signals from a same high-level voltage signal line, and the second voltage input terminal 2102 and the third voltage input terminal 2103 can receive a low-level signal from a same low-level voltage signal line. The above configuration reduces number of high-level voltage signal lines and low-level voltage signal lines, minimizes signal lines needed in a shift register circuit, which supports the display panel in achieving a narrow frame and simplifies a structure and design of external drive devices and flexible circuit boards.

In other embodiments, the first voltage input terminal 2101 and the fourth voltage input terminal 2104 can receive same high-level signals, and the second voltage input terminal 2102 and the third voltage input terminal 2103 can receive a same low-level signal. However, the voltage signal lines connected to the first voltage input terminal 2101 and the fourth voltage input terminal 2104 may be different signal lines, and similarly, the voltage signal lines connected to the second voltage input terminal 2102 and the third voltage input terminal 2103 may also be different signal lines.

FIGS. 16-18 illustrate three additional schematic diagrams of a shift register in the driving circuit shown in FIG. 8. The following will introduce a specific structure, and an operational process of a shift register in one embodiment, with reference to structures of shift registers shown in FIGS. 16-18. The shift registers shown in FIGS. 16-18 correspond to specific circuit structures of the shift registers shown in FIGS. 9, 14 and 15. In other embodiments, same structures of shift registers can refer to the structures of shift registers shown in FIGS. 16-18, such as shift registers shown in FIGS. 11-13.

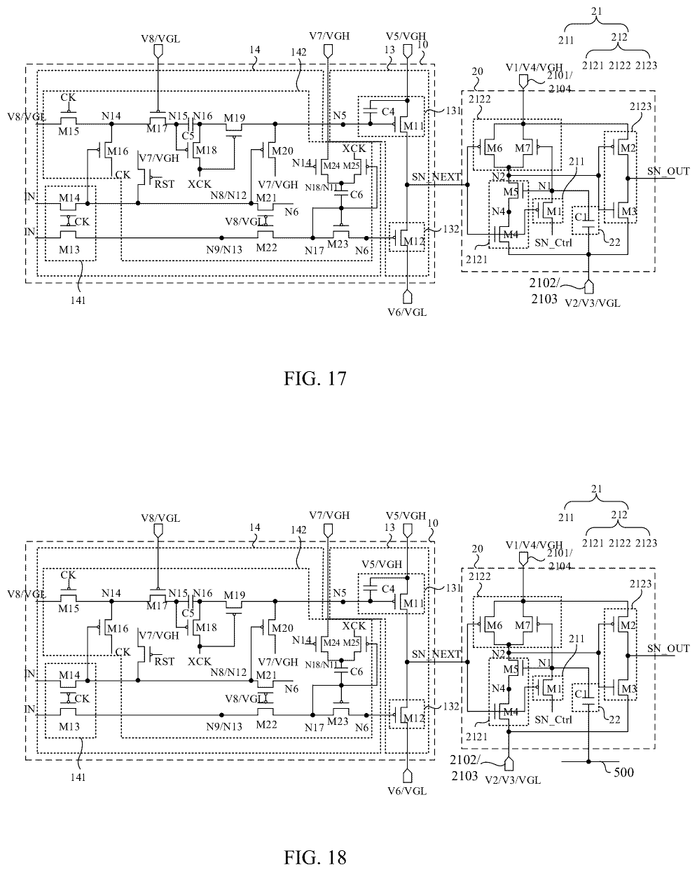

In one embodiment, the first voltage stabilizing unit 22 may include at least one capacitor. As shown in FIGS. 16 and 17, the first voltage stabilizing unit 22 may include a first capacitor C1. A first terminal of the first capacitor C1 is connected to the first node N1 in the control unit 21, and a second terminal of the first capacitor C1 is connected to the low-level signal VGL, as shown in FIG. 16, or to the fixed voltage signal line 500, as shown in FIG. 17.

Referring to FIGS. 16-18, the first control unit 211 in the control unit 21 may include a first transistor M1. A gate of the first transistor M1 receives the first output signal SN_NEXT, a first electrode of the first transistor M1 receives the frequency control signal SN_Ctrl, and a second electrode of the first transistor M1 is electrically connected to the first node N1.

Optionally, referring to FIGS. 16-18, the first transistor M1 is a P-channel transistor. For the first transistor M1, the invalid pulse of the first output signal SN_NEXT is a low-level signal, and the valid pulse is a high-level signal. Optionally, in one embodiment, the first transistor M1 may also be an N-channel transistor. The invalid pulse of the first output signal is a high-level signal, and the valid pulse is a low-level signal.

Referring to FIGS. 16-18, for the second control unit 212 in the control unit 21, the third module 2123 includes the second transistor M2 and the third transistor M3 and channel types of the second transistor M2 and the third transistor M3 are different. A first electrode of the second transistor M2 receives the first voltage signal V1, and a second electrode of the second transistor M2 outputs the second output signal SN_OUT, a gate of the second transistor M2 is electrically connected to the second node N2. A first electrode of the third transistor M3 receives the second voltage signal V2, a second electrode of the third transistor M3 outputs the second output signal SN_OUT, and a gate of the third transistor M3 is electrically connected to the second node N2.

In one embodiment, the second transistor M2 is exemplified as a P-type channel transistor, while the third transistor M3 is exemplified as an N-type channel transistor. Since the gates of the second transistor M2 and the third transistor M3 are both connected to the second node N2, and channel types of the second transistor M2 and the third transistor M3 are different, the third module 2123 essentially controls one of the second transistor M2 and the third transistor M3 to turn on and the other of the second transistor M2 and the third transistor M3 to turn off through the second node N2. The second output signal SN_OUT can only alternately output the first voltage signal V1 and the second voltage signal V2, thereby forming valid pulses and invalid pulses.

The first module 2121 of the second control unit 212 in the control unit 21 may include a fourth transistor M4 and a fifth transistor M5. A first electrode of the fourth transistor M4 receives the third voltage signal V3, a second electrode of the fourth transistor M4 is electrically connected to a fourth node N4, and a gate of the fourth transistor M4 receives the first output signal SN_NEXT. A first electrode of the fifth transistor M5 is electrically connected to the fourth node N4, a second electrode of the fifth transistor M5 is electrically connected to the second node N2, and a gate of the fifth transistor M5 is electrically connected to the first node N1.

The second module 2122 of the second control unit 212 in the control unit 21 may include a sixth transistor M6 and a seventh transistor M7. A first electrode of the sixth transistor M6 receives the fourth voltage signal V4, a second electrode of the sixth transistor M6 is electrically connected to the second node N2, and a gate of the sixth transistor M6 receives the first output signal SN_NEXT. A first electrode of the seventh transistor M7 receives the fourth voltage signal V4, a second electrode of the seventh transistor M7 is electrically connected to the second node N2, and a gate of the seventh transistor M7 is electrically connected to the first node N1.

Referring to FIG. 9 and FIG. 16, optionally, the voltage of the high-level signal from the first voltage signal V1 and the second voltage signal V2 is VGH1, while the voltage of the high-level signal from the third voltage signal V3 and the fourth voltage signal V4 is VGH2, where VGH1>VGH2. And/or the voltage of the low-level signal from the first voltage signal V1 and the second voltage signal V2 is VGL1, while the voltage of the low-level signal from the third voltage signal V3 and the fourth voltage signal V4 is VGL2, where VGL1<VGL2.

As described in the embodiments of FIG. 9 and FIG. 16, in the first voltage signal V1 and the second voltage signal V2, the first voltage signal V1 is a high-level signal, that is, V1=VGH1, while the second voltage signal V2 is a low-level signal, that is, V2=VGL1. In the third voltage signal V3 and the fourth voltage signal V4, the fourth voltage signal V4 is a high-level signal, that is, V4=VGH2, while the third voltage signal V3 is a low-level signal, that is, V3=VGL2. In one embodiment, VGH1>VGH2, and VGL1<VGL2, that is, V1>V4, and V2<V3, which indicates that the high-level voltage signal VGH1 received by the first electrode of the second transistor M2 is higher than the high-level voltage signal VGH2 received by the sixth transistor M6 and the seventh transistor M7. The low-level voltage signal VGL1 received by the first electrode of the third transistor M3 is lower than the low-level voltage signal VGL2 received by the first electrode of the fourth transistor M4. Therefore, when the second transistor M2 and the third transistor M3 respectively output the second output signal SN_OUT, it can be ensured that the on-state can work more likely in a saturation state, and the off-state can be better deactivated, reducing a power consumption of the second transistor M2 and the third transistor M3, ensuring that the voltage of a valid pulse of the second output signal SN_OUT is same as the high-level voltage signal VGH1, and the voltage of an invalid pulse is the same as the low-level voltage signal VGL1, thereby ensuring a normal driving of the pixel circuit by the second output signal SN_OUT.

Referring to FIG. 10 and FIG. 17, an example of a control logic and control process of the second control part of the shift register is introduced. It should be noted that the first transistor M1, the second transistor M2, the sixth transistor M6 and the seventh transistor M7 are P-type channel transistors with low-level conduction, whose control terminals receive valid pulses as low-level signals, and the invalid pulses as high-level signals. The third transistor M3, the fourth transistor M4 and the fifth transistor M5 are N-channel transistors with high-level conduction, whose control terminals receive valid pulses as high-level signals, and the invalid pulses as low-level signals.

In a zeroth stage t0, the first output signal SN_NEXT is at a high level, and the frequency control signal SN_Ctrl switches from a low level to a high level. The first transistor M1 and the sixth transistor M6 are turned off, and the fourth transistor M4 is turned on. The first node N1 remains in a low-level state from a previous stage (when the first output signal SN_NEXT and the frequency control signal SN_Ctrl were at a low level, equivalent to a fourth stage t4). The fifth transistor M5 is turned off, while the seventh transistor M7 is turned on, allowing the fourth voltage signal V4 (the high-level signal VGH) to be input to the second node N2 through the seventh transistor M7, so that the second node N2 is in a high-level state. The second transistor M2 is turned off, while the third transistor M3 is turned on. The second voltage signal V2 (the low-level signal VGL) is then output through the third transistor M3, resulting in the second output signal SN_OUT being an invalid pulse, i.e., at a low level.

In a first stage t1, the first output signal SN_NEXT is at a low level and the frequency control signal SN_Ctrl is at a high level. The first transistor M1 and the sixth transistor M6 are turned on, and the fourth transistor M4 is turned off. The frequency control signal SN_Ctrl is input to the first node N1 through the first transistor M1, charging the first capacitor C1 and maintaining the first node N1 in a high-level state. The fifth transistor M5 is turned on, while the seventh transistor M7 and the fourth transistor M7 are turned off. The voltage signal V4 (the high-level signal VGH) is input to the second node N2 through the sixth transistor M6, so that the second node N2 is in a high-level state. The second transistor M2 is turned off, the third transistor M3 is turned on, and the second voltage signal V2 (low-level signal VGL) is output through the third transistor M3, making the second output signal SN_OUT an invalid pulse, i.e., at a low level.

In a second stage t2, both the first output signal SN_NEXT and the frequency control signal SN_Ctrl are at a high level. The first transistor M1 and the sixth transistor M6 are turned off, while the fourth transistor M4 is turned on. The first capacitor C1 discharges, keeping the voltage of the first node N1 at a high-level state of a previous stage, that is, the first stage t1. The fifth transistor M5 is turned on, the seventh transistor M7 is turned off, and the third voltage signal V3 (the low level signal VGL) is input to the second node N2 through the fourth transistor M4 and the fifth transistor M5, so that the second node N2 is in a low-level state. The second transistor M2 is turned on, the third transistor M3 is turned off, and the first voltage The signal V1 (high-level signal VGH) is output through the second transistor M2, making the second output signal SN_OUT a valid pulse, i.e., at a high level.

In a third stage t3, the first output signal SN_NEXT is at a high level, and the frequency control signal SN_Ctrl switches from a high level to a low level. The first transistor M1 and the sixth transistor M6 are turned off, while the fourth transistor M4 is turned on. The first node N1 can continue to maintain a high-level state through a discharge of the first capacitor C1. The fifth transistor M5 is turned on, the seventh transistor M7 is turned off, allowing the third voltage signal V3 (the low-level signal VGL) to be input to the second node N2 through the fourth transistor M4 and the fifth transistor M5. The second node N2 is in a low-level state, the second transistor M2 is turned on, and the third transistor M3 is turned off. The first voltage signal V1 (the high-level signal VGH) is output through the second transistor M2, making the second output signal SN_OUT is a valid pulse, i.e., at a high level.

In a fourth stage t4, both the first output signal SN_NEXT and the frequency control signal SN_Ctrl are at a low level. The first transistor M1 and the sixth transistor M6 are turned on, while the fourth transistor M4 is turned off. The frequency control signal is input to the first node N1 through the first transistor M1 and charges the first capacitor C1. The first node N1 is in a low-level state, the fifth transistor M5 is turned off, the seventh transistor M7 is turned on, and the fourth voltage signal V4 (the high-level signal VGH) is input to the second node N2 through the sixth transistor M6, so that the second node N2 is in a high-level state. The second transistor M2 is turned off, the third transistor M3 is turned on, and the second voltage signal V2 (Low-level signal VGL) is output through the third transistor M3, making the second output signal SN_OUT an invalid pulse, i.e., at a low level.

In a fifth stage t5, the first output signal SN_NEXT is at a high level, while the frequency control signal SN_Ctrl is low level. The first transistor M1 and the sixth transistor M6 are turned off, while the fourth transistor M4 is turned on. The node N1 can continue to maintain a low-level state through a discharge of the first capacitor C1. The fifth transistor M5 is turned off, the seventh transistor M7 is turned on, and the fourth voltage signal V4 (the high-level signal VGH) is input through the sixth transistor. M6 to the second node N2, so that the second node N2 is in a high-level state. The second transistor M2 is turned off, the third transistor M3 is turned on, and the second voltage signal V2 (the low-level signal VGL) is output through the third transistor M3, making the second output signal SN_OUT an invalid pulse, i.e., at a low level.

For the zero stage t0 and the third stage t3, since the first output signal SN_NEXT is high level in both two stages, the first transistor M1 is turned off. Therefore, the frequency control signal SN_Ctrl signal cannot be written to the first node N1 and an output of the second output signal SN_OUT cannot be controlled through the first node N1. However, since the first transistor M1 can act as a resistor, the frequency control signal SN_Ctrl will still influence the voltage of the first node N1 to some extent through the first transistor M1 during a transition. Additionally, a level signal connected to the second terminal of the first capacitor C1 is affected through the first capacitor C1.

In the third stage t3, the second transistor M2 is turned on, and the second output signal SN_OUT actually outputs the first voltage signal V1 provided by the first voltage input terminal 2101. Since the second terminal of the first capacitor C1 is electrically insulated from the first voltage input terminal 2101, the first capacitor C1 does not affect the second output signal SN_OUT. In the zeroth stage t0, the third transistor M3 is turned on, and the second output signal SN_OUT actually outputs the second voltage signal V2 provided by the second voltage input terminal 2102. Although the second terminal of the first capacitor C1 is electrically connected to the second voltage input terminal 2102, causing fluctuations in the second output signal SN_OUT when outputting the second voltage signal V2, resulting in ripples as shown in FIG. 10, However, since the second output signal SN_OUT is in the invalid pulse stage in the third stage, the second output signal SN_OUT will not affect the connected pixel circuit and a display quality of the display panel.

Therefore, in other embodiments, because the second terminal of the first capacitor C1 in the shift register is electrically insulated from the first voltage input terminal 2101 for outputting valid pulses, as shown in FIGS. 9 and 12, the second terminal of the first capacitor C1 can instead be electrically connected to a low-level signal terminal for outputting invalid pulses, Alternatively, as shown in FIG. 11, the second terminal of the first capacitor C1 can instead be electrically connected to an additional fixed voltage signal line 500, or, as shown in FIG. 13, the second terminal of the first capacitor C1 can instead be electrically connected to any other high-level signal not used for outputting valid pulses, so that when the second output signal SN_OUT is output, the second output signal SN_OUT will not be interfered by fluctuations in the frequency control signal SN_Ctrl to generate ripples. Even if ripples are generated, the ripples will only be generated in the invalid pulse stage of the second output signal SN_OUT, thereby preventing any impact on the pixel circuit driven by the shift register, effectively resolving the issue of dark or bright lines in junctions of different partitions in a display panel with the partition frequency adjustment function, which can result in abnormal displays.

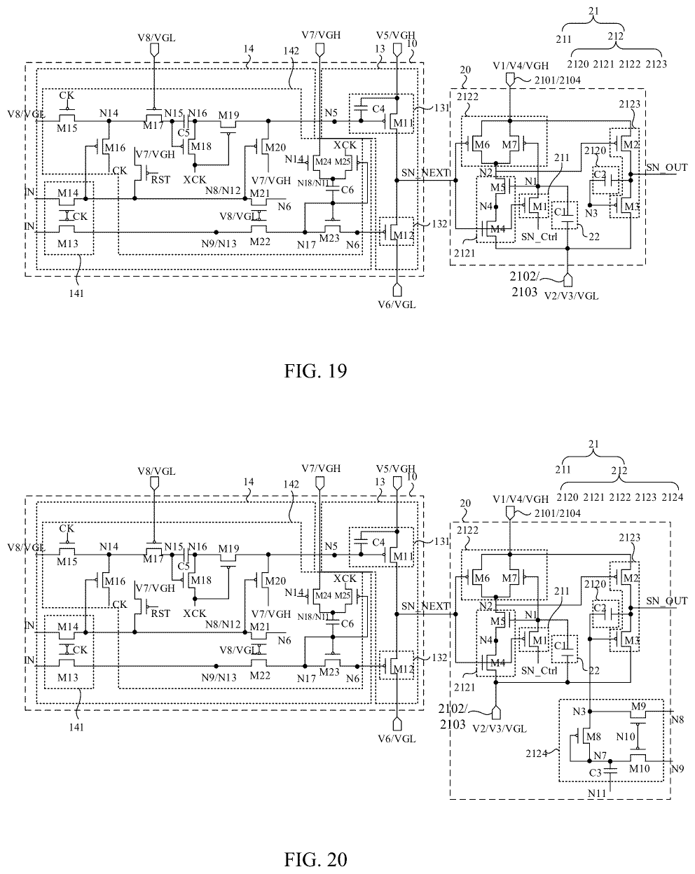

FIG. 19 illustrates another schematic diagram of a shift register in the driving circuit shown in FIG. 8. Optionally, in one embodiment, referring to FIG. 19, the third module 2123 includes the second transistor M2 and the third transistor M3, both of which have a same channel type. The first electrode of the second transistor M2 receives the first voltage signal V1, the second electrode of the second transistor M2 outputs the second output signal SN_OUT, and the gate of the second transistor M2 is electrically connected to the second node N2. The first electrode of the third transistor M3 receives the second voltage signal V2, the second electrode of the third transistor M3 outputs the second output signal SN_OUT, and the gate of the third transistor M3 is electrically connected to a third node N3. The third node N3 is an electrical connection node in the first control part 10. In the embodiment, the second transistor M2 and the third transistor M3 are both PMOS transistors or both NMOS transistors (both are PMOS transistors in FIG. 19). The gate of the second transistor M2 is connected to the second node N2, while the gate of the third transistor M3 is connected to the third node N3. Through the second node N2 and the third node N3, one of the second transistor M2 and the third transistor M3 is controlled to be turned on while the other is controlled to be turned off, resulting in the second output signal SN_OUT alternating between valid pulses and invalid pulses. It should be noted that in the embodiment, the node in the first control part 10 is essentially extracted as the third node N3, whose specific position and connection within the first control part 10 will be described in detail later.

As shown in FIG. 19, the third transistor M3 is a PMOS transistor, a gate of which is connected to the third node N3 for conduction control. Since the second output signal SN_OUT is generally an invalid pulse or at a low-level state for a long time, the third transistor M3 needs to remain on for a long time. When the third transistor M3 is configured as an NMOS transistor, the gate of the third transistor M3 receives a high-level signal for an extended period, so that the threshold of the NMOS transistor shifts, resulting in unstable electrical characteristics and abnormal switching behavior. On the other hand, setting the third transistor M3 as a PMOS transistor, which is turned on when the gate of the third transistor M3 is at a low level, will prevent threshold drifts, avoid shifts in the transistor characteristic curve, ensure a stability of electrical characteristics of the third transistor M3, and avoid a risk of abnormal switching.

Optionally, referring to FIG. 19, in one embodiment, the second control unit 212 also includes a second voltage stabilizing unit 2120. a first terminal of the second voltage stabilizing unit 2120 is electrically connected to the gate of the third transistor M3, while a second terminal of the second voltage stabilizing unit 2120 is electrically connected to the second electrode of the third transistor M3. Specifically, the second voltage stabilizing unit 2120 may also include at least one capacitor. As shown in FIG. 19, the second voltage stabilizing unit 2120 includes a second capacitor C2.

The second voltage stabilizing unit 2120 stabilizes the second output signal SN_OUT. Since the first terminal of the second voltage stabilizing unit 2120 is electrically connected to the gate of the third transistor M3, the second voltage stabilizing unit 2120 can store a control signal from the control terminal of the third transistor M3 within a certain period and maintain the state of the third transistor M3. Specifically, when the second voltage stabilizing unit 2120 is not provided, the gate of the third transistor M3 is directly controlled by the voltage of the third node N3. When the voltage of the third node N3 changes, switching from receiving a valid pulse to receiving a valid pulse, the third transistor M3 transitions from a turning-off state to a turning-on state. During the above process, the second transistor M2 and the third transistor M3 are jointly responsible for an output of the second output signal SN_OUT, and the second output signal SN_OUT transitions from a high level to a low level. There will be redundant steps in the transition process, resulting in a transition delay of the second output signal SN_OUT, affecting a control of the pixel circuit by the second output signal SN_OUT. In the embodiment, by setting the second voltage stabilizing unit 2120, specifically the second capacitor C2, when the third transistor M3 is turned on in response to a valid pulse, the second capacitor C2 is charged, effectively storing the valid pulse. When the third transistor M3 switches to receive an invalid pulse, the second capacitor C2 is discharged, maintaining the valid pulse of the third transistor M3 for a certain duration, so that the third transistor M3 can remain in a turning-on state for the certain duration, ensuring that the second output signal SN_OUT can output a complete invalid pulse signal. On the other hand, when the third transistor M3 switches from receiving invalid pulses to receiving valid pulses, the second voltage stabilizing unit 2120 can remain in a turning-off state for a certain duration, ensuring that the second output signal SN_OUT can output a complete valid pulse signal. Therefore, the second voltage stabilizing unit 2120 eliminates the redundant steps during a high-low level transition of the second output signal SN_OUT, avoids pulse signal delays, and ensures accurate control and normal operation of the pixel circuit.

In other embodiments, the second voltage stabilizing unit 2120 can also be connected in parallel to the gate and second electrode of the third transistor M3, so that the operational state of the third transistor M3 is maintained within a certain period, thereby ensuring an integrity of a pulse signal of the second output signal SN_OUT, which is not illustrated herein.

As a previous embodiment describes an internal structure of the second control part in the shift register and a working principle of outputting the second output signal according to the first output signal and the frequency control signal for the first control part, the following will introduce an internal structure of the first control part and a working principle of controlling the first output signal.

Referring to FIGS. 9 and 11-19, optionally, the first control part 10 includes a third control unit 13, and the third control unit 13 includes a first output module 131 and a second output module 132. One terminal of the first output module 131 receives the fifth voltage signal V5, the other terminal of the first output module 131 outputs the first output signal SN_NEXT. A control terminal of the first output module 131 is connected to the fifth node N5. One terminal of the second output module 132 receives the sixth voltage signal V6, the other terminal of the second output module 132 outputs the first output signal SN_NEXT. A control terminal of the second output module 132 is connected to the sixth node N6. One of the fifth voltage signal V5 and the sixth voltage signal V6 is a high-level signal, while the other is a low-level signal.

The first output module 131 and the second output module 132 are turned on or off according to a signal from a node whose control terminal is connected, thereby outputting the fifth voltage signal V5 through the first output module 131 or outputting the sixth voltage signal V6 through the second output module 132. It can be understood that since one of the fifth voltage signal V5 and the sixth voltage signal V6 is a high-level signal while the other is a low-level signal, an output control of the third control unit 13 allows the first output signal SN_NEXT to switch between valid pulses and invalid pulses, thereby controlling a timing of the first output signal SN_NEXT.

Referring to FIGS. 9 and 11-19, the third control unit 13 in the first control part 10 includes the first output module 131 and the second output module 132. For example, the first output module 131 may include an eleventh transistor M11 and a fourth capacitor C4, while the second output module 132 may include a twelfth transistor M12. A gate of the eleventh transistor M11 is connected to the fifth node N5, a source of the eleventh transistor M11 receives the fifth voltage signal V5 (a high-level signal shown in figures), and a drain of the eleventh transistor M11 outputs the first Output signal SN_NEXT. A first plate of the fourth capacitor C4 receives the fifth voltage signal V5, a second plate of the fourth capacitor C4 is connected to a gate of the eleventh transistor M11. A gate of the twelfth transistor M12 is connected to the sixth node N6, and the source of the twelfth transistor M12 receives the sixth voltage signal V6 (a low-level signal shown in figures), and a drain of the twelfth transistor M12 outputs the first signal SN_NEXT.

Based on the structure of the third control unit 13 described above, in one embodiment, the low-level signal from the first voltage signal V1 and the second voltage signal V2 and the low-level signal from the fifth voltage signal V5 and the sixth voltage signal V6 are signals with a same voltage; and/or the high-level signal from the first voltage signal V1 and the second voltage signal V2 and a high-level signal from the fifth voltage signal V5 and the sixth voltage signal V6 signal are signals with a same voltage; and/or, the low-level signal from the third voltage signal V3 and the fourth voltage signal V4 and the low-level signal from the fifth voltage signal V5 and the sixth voltage signal V6 are signals with a same voltage; and/or, the high-level signal from the third voltage signal V3 and the fourth voltage signal V4 and the high-level signal from the fifth voltage signal V5 and the sixth voltage signal V6 are signals with a same voltage. As shown in FIGS. 17-19, the fifth voltage signal V5, the first voltage signal V1 and the fourth voltage signal V4 are the same high-level signal VGH, the sixth voltage signal V6, the second voltage signal V2 and the third voltage Signal V3 is the same low-level signal VGL.

The essence of the embodiment is to multiplex at least two high-level signals, or multiplex at least two low-level signals, thereby reducing number of high-level signal lines or low-level signal lines, which facilitates a wiring layout, simplifies a circuit structure of the shift register 110, and reduces a complexity of the shift register 110.

Referring to FIGS. 9 and 11-19, in one embodiment, the first control part 10 also includes a fourth control unit 14, which is configured for receiving an input signal IN, the third voltage signal V3 and the fourth voltage signal V4, a first clock signal CK and/or a second clock signal XCK, to control the voltages of the fifth node N5 the sixth node N6.

Specifically, the fourth control unit 14 may include a first control module 141 and a second control module 142. The first control module 141 is configured for receiving the input signal IN and control signals of a twelfth node N12 and a thirteenth node N13 in response to the first clock signal CK. The twelfth node N12 is connected to the sixth node N6. The second control module 142 is configured for receiving a seventh voltage signal V7 and an eighth voltage signal V8 and controls a signal from the fifth node N5 in response to signals of the twelfth node N12 and the thirteenth node N13, the first clock signal CK and the second clock signal XCK. One of the seventh voltage signal V7 and the eighth voltage signal V8 is a high-level signal, while the other is a low-level signal.

Specifically, the first control module 141 includes a thirteenth transistor M13 and a fourteenth transistor M14. A source of the thirteenth transistor M13 is connected to the input signal IN, a drain of the thirteenth transistor M13 is connected to the twelfth node N12 and a gate of the thirteenth transistor M13 is connected to the first clock signal CK. A source of the fourteenth transistor M14 is connected to the input signal IN, a drain of the fourteenth transistor M14 is connected to the thirteenth node N13, and a gate of the fourteenth transistor M14 is connected to the first clock signal CK.

Specifically, the second control module 142 includes a fifteenth transistor M15, a sixteenth transistor M16, a seventeenth transistor M17, an eighteenth transistor M18, a nineteenth transistor M19, a twentieth transistor M20, a twenty-first transistor M21, a twenty-second transistor M22, a twenty-third transistor M23, a twenty-fourth transistor M24, a twenty-fifth transistor M25, a fifth capacitor C5 and a sixth capacitor C6.

A source of the fifteenth transistor M15 receives the eighth voltage signal V8 (a low-level signal shown in figures), a gate of the fifteenth transistor M15 receives the first clock signal CK, and a drain of the fifteenth transistor M15 is connected to the fourteenth node N14. A gate of the sixteenth transistor M16 is connected to the twelfth node N12, a source of the sixteenth transistor M16 receives the first clock signal CK, and a drain of the sixteenth transistor M16 is connected to the fourteenth node N14. A source of the seventeenth transistor M17 is connected to the fourteenth node N14, a gate of the seventeenth transistor M17 receives the eighth voltage signal V8 and a drain of the seventeenth transistor M17 is connected to the fifteenth node N15. A source of the eighteenth transistor M18 receives the second clock signal XCK, a gate of the eighteenth transistor M18 is connected to the fifteenth node N15, and a drain of the eighteenth transistor M18 is connected to the sixteenth node N16. A first plate of the fifth capacitor C5 is connected to the fifteenth node N15, and a second plate of the fifth capacitor C5 is connected to the sixteenth node N16. A source of the nineteenth transistor M19 is connected to the sixteenth node N16, a drain of the nineteenth transistor M19 is connected to the fifth node N5, and a gate of the nineteenth transistor M19 receives the second clock signal XCK. A source of the twentieth transistor M20 receives the seventh voltage signal V7 (a high-level signal shown in figures), a drain of the twentieth transistor M20 is connected to the fifth node N5, and a gate of the twentieth transistor M20 is connected to the twelfth node N12. A source of the twenty-first transistor M21 is connected to the twelfth node N12, a drain of the twenty-first transistor M21 is connected to the sixth node N6, and a gate of the twenty-first transistor M21 receives the eighth voltage signal V8. A source of the twenty-second transistor M22 is connected to the thirteenth node N13, a drain of the twenty-second transistor M22 is connected to the seventeenth node N17, and a gate of the twenty-second transistor M22 receives the eighth voltage signal V8. A source and a gate of the twenty-third transistor M23 are both connected to the seventeenth node N17, and a drain of the twenty-third transistor M23 is connected to the sixth node N6. A first plate of the sixth capacitor C6 is connected to the seventeenth node N17, and a second plate of the sixth capacitor C6 is connected to the eighteenth node N18. A source of the twenty-fourth transistor M24 receives the Seven voltage signal V7, a drain of the twenty-fourth transistor M24 is connected to the eighteenth node N18, and a gate of the twenty-fourth transistor M24 is connected to the fourteenth node N14. A source of the twenty-fifth transistor M25 receives the second clock signal XCK, a drain of the twenty-fifth transistor M25 is connected to the eighteenth node N18, and a gate of the twenty-fifth transistor M25 is connected the seventeenth node N17.

The low-level signal from the seventh voltage signal V7 and the eighth voltage signal V8 and the low-level signal from the fifth voltage signal V5 and the sixth voltage signal V6 are signals with a same voltage; and/or the high-level signal from the seventh voltage signal V7 and the eighth voltage signal V8 and the high-level signal from the fifth voltage signal V5 and the sixth voltage signal V6 are signals with a same voltage. As shown in FIGS. 17 to 19, the seventh voltage signal V7 is the high-level signal VGH, and the eighth voltage signal is the low-level signal VGL.

In one embodiment, as shown in FIG. 19, optionally, the third node N3 and the sixth node N6 are a same node.

The gate of the third transistor M3 in the third module 2123 is essentially connected to a same node as the control terminal of the first output module 131. Therefore, the third module 2123 can be driven synchronously with the second output module 132, and when the second output module 132 switches between on and off, the third module 2123 also switches turning-on and turning-off states. Therefore, when the second output module 132 outputs valid or invalid pulses, the third module 2123 can also directly output valid or invalid pulses, thereby simplifying a control logic and control circuit structure of the third module 2123 and simplify the control circuit structure.

In other embodiments, optionally, the third node N3 and the fifth node N5 are same nodes. When the second output module 132 outputs valid or invalid pulses, the third module 2123 can also directly output valid or invalid pulses.

A control terminal of the third module 2123 is connected to a same node as the control terminal of either the first output module 131 or the second output module 132, and the connection needs to be configured according to a switching timing of the first output module 131 or the second output module 132 and a switching timing of the third module 2123. As shown in FIG. 18, since the third module 2123 and the second output module 132 need to switch synchronously, when the third module 2123 and the second output module 132 are both configured as PMOS transistors, control terminals of the third module 2123 and the second output module 132 can be connected to a same node, that is, the sixth node N6. A person skilled in the art can also arrange the third transistor M3 in the third module 2123 as an N-channel transistor and the eleventh transistor M11 in the first output module 131 as a PMOS transistor. Control terminals of the third transistor M3 in the third module 2123 and the eleventh transistor M11 in the first output module 131 are connected to a same node, that is, the fifth node N5. Types of transistors and the connection methods of the control terminals of the third module 2123, the first output module 131 and the second output module 132 are examples and are not limited herein.

Based on a consideration of sharing nodes in the first control part, in one embodiment, a shift register structure utilizing the above structure of the first control part is provided. FIG. 20 illustrates another schematic diagram of a shift register in the driving circuit shown in FIG. 8. Referring to FIG. 20, in the embodiment, the second control unit 212 also includes a fourth module 2124. The fourth module 2124 includes an eighth transistor M8, a ninth transistor M9, and a tenth transistor M10. A first electrode of the eighth transistor M8 is connected to the third node N3, a second electrode of the eighth transistor M8 is connected to the seventh node N7, and a gate of the eighth transistor M8 is connected to the second electrode. A first electrode of the ninth transistor M9 is connected to the eighth node N8, a second electrode of the ninth transistor M9 is connected to the third node N3, and a gate of the ninth transistor M9 is connected to the tenth node N10. A first electrode of the tenth transistor M10 is connected to the ninth node N9, a second electrode of the tenth transistor M10 is connected to the seventh node N7, and the gate of the tenth transistor M10 is connected to the tenth node N10.

Further, referring to FIG. 20, in one embodiment, the fourth module 2124 also includes a third capacitor C3. A first plate of the third capacitor C3 is connected to the eleventh node N11, and a second plate of the third capacitor C3 is connected to the seventh node N7.

The eighth node N8 and the twelfth node N12 are a same node; the ninth node N9 and the thirteenth node N13 are a same node; and the eleventh node N11 and the eighteenth node N18 are a same node.

The eighth transistor M8, the ninth transistor M9, the tenth transistor M10, the eleventh transistor M11, and the second capacitor C3 in the fourth module 2124 essentially have a same structure as the twenty-first transistor M21, the twenty-second transistor M22, the twenty-third transistor M23 and the fifth capacitor C6. The fourth module 2124 in the second control part 20 generates a signal that is completely synchronized with the signal on the sixth node N6 under a control of signals on the twelfth node N12 and the thirteenth node N13, and thereby controlling the third transistor M3. In one embodiment shown in FIG. 20, the fourth module 2124 can not only generate a control signal synchronized with a signal on the sixth node N6, so that the fourth module 2124 can synchronously control the twelfth transistor M12, but the fourth module 2124 can also isolate an influence of the gate of the twelfth transistor M12, that is, the sixth node N6 to a certain extent. The isolation can avoid abnormal switching of the third transistor M3 caused by unstable signals on the sixth node N6, resolve an interference between the gate of the third transistor M3 and the switching of the twelfth transistor M12, stabilize the gate voltage of the twelfth transistor M12, and avoid abnormal switching of the twelfth transistor M12.

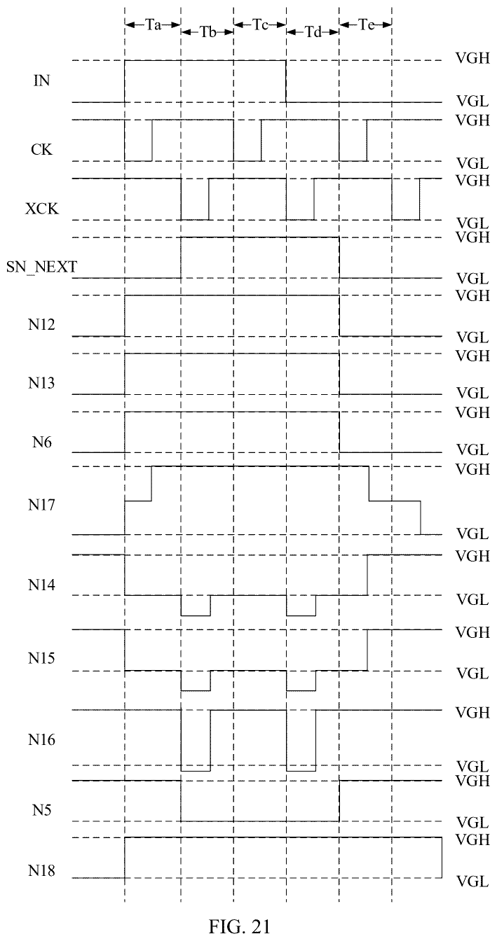

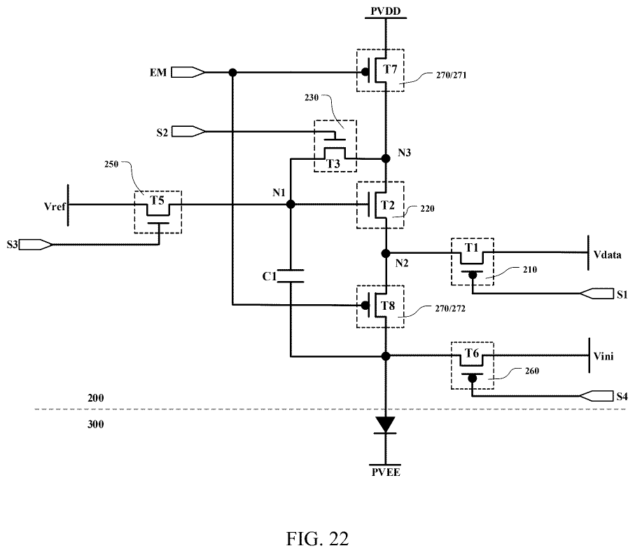

FIG. 21 illustrates a driving timing diagram of a first control unit in the shift register shown in FIG. 20. Referring to FIG. 20 and FIG. 21, the following will introduce a working principle and a working process of the first control unit in the shift register in one embodiment.

In a Ta stage, the input signal IN is at a high level and the first clock signal CK is at a low level. The thirteenth transistor M13, the fourteenth transistor M14 and the fifteenth transistor M15 are turned on. The input signal IN is transmitted to the twelfth node N12 and the thirteenth node N13 respectively through the thirteenth transistor M13 and the fourteenth transistor M14, so that the twelfth node N12 and the thirteenth node N13 are both at a high level. The sixteenth transistor M16 and the twentieth transistor M20 are turned off. The eighth voltage signal V8 (the low-level signal VGL) is transmitted to the fourteenth node N14 through the fifteenth transistor M15. The fourteenth node N14 is at a low level, and the seventeenth transistor M17 is turned on, the fifteenth node N15 is at a low level, the eighteenth transistor M18 is turned on, the second clock signal XCK is at a high level, the sixteenth node N16 remains at a high level, the nineteenth transistor M19 is turned off, and the fifth node N5 remains at a low level, the eleventh transistor M11 is turned on, and the fifth voltage signal V5 (high-level signal VGH) is transmitted to the output terminal, so that the first output signal SN_NEXT is at a high level.

In a Tb stage, the input signal IN is at a high level and the first clock signal CK is at a high level. The thirteenth transistor M13, the fourteenth transistor M14 and the fifteenth transistor M15 are turned off, and the twelfth node N12 and the thirteenth node N13 remain at a high level. The sixteenth transistor M16 and the twentieth transistor M20 are turned off, and the fourteenth node N14 remains at a low level. The eighteenth transistor M18 is turned on, the second clock signal XCK is at a low level and is transmitted to the sixteenth node N16 through the eighteenth transistor M18, so that the sixteenth node N16 is at a low level. The eighteenth transistor M18 is turned on, the signal from the sixteenth node N16 is transmitted to the fifth node N5, so that the fifth node N5 is at a low level. The eleventh transistor M11 is turned on, and the fifth voltage signal V5 (high-level signal VGH) is transmitted to the output terminal, so that the first output signal SN_NEXT is at a high level.

In a Tc stage, the input signal IN is at a high level and the first clock signal CK is at a low level. The thirteenth transistor M13, the fourteenth transistor M14 and the fifteenth transistor M15 are turned on, and the input signal IN is transmitted to the twelfth node N12 and the thirteenth node N13 through the thirteenth transistor M13 and the fourteenth transistor M14 respectively, so that the twelfth node N12 and the thirteenth node N13 are both at a high level. The sixteenth transistor M16 and the twentieth transistor M20 is turned off. The eighth voltage signal V8 (the low-level signal VGL) is transmitted to the fourteenth node N14 through the fifteenth transistor M15. The fourteenth node N14 is at a low level, and the seventeenth transistor M17 is turned on, the fifteenth node N15 is at a low level, the eighteenth transistor M18 is turned on. The second clock signal XCK is a high level, the sixteenth node N16 remains at a high level. The nineteenth transistor M19 is turned off, and the fifth node N5 remains at al ow level. The eleventh transistor M11 is turned on, and the fifth voltage signal V5 (high-level signal VGH) is transmitted to the output terminal, so that the first output signal SN_NEXT is at a high level.

In a Td stage, the input signal IN is at a low level, the first clock signal CK is at a high level. The thirteenth transistor M13, the fourteenth transistor M14 and the fifteenth transistor M15 are all turned off, the twelfth node N12 and the fifteenth transistor M15 are all turned off. The thirteenth node N13 maintains a high level, the sixteenth transistor M16 and the twentieth transistor M20 are both turned off. The fourteenth node N14 remains at a low level, and the seventeenth transistor M17 is turned on. The fifteenth node N15 is at a low level, the eighteenth transistor M18 is turned on, the second clock signal XCK is at a low level, the second clock signal XCK is transmitted to the sixteenth node N16 through the eighteenth transistor M18, so that the sixteenth node N16 is at a low level. The nineteenth transistor M19 is turned on, and a signal from the sixteenth node N16 is transmitted to the fifth node N5, which is at a low level. The eleventh transistor M11 is turned on, and the fifth voltage signal V5 (the high-level signal VGH) is transmitted to an output terminal, so that the first output signal SN_NEXT is at a high level.

In a Te stage, the input signal IN is at a low level, the first clock signal CK is at a low level. The thirteenth transistor M13, the fourteenth transistor M14 and the fifteenth transistor M15 are turned on. The input signal IN is transmitted to the thirteenth transistor M13 and the fourteenth transistor M14 are transmitted to the twelfth node N12 and the thirteenth node N13 respectively, so that the twelfth node N12 and the thirteenth node N13 are both at low level and the sixteenth transistor M16 and the twentieth transistor M20 are turned on. The fifteenth transistor M15 is turned on, the eighth voltage signal V8 (the low-level signal VGL) is transmitted to the fourteenth node N14 through the fifteenth transistor M15. The fourteenth node N14 is at a low level, and the seventeenth transistor M17 is turned on. The fifteenth node N15 is at a low level, and the eighteenth transistor M18 is turned on. The second clock signal XCK is at a high level, the sixteenth node N16 remains at a high level, and the nineteenth transistor M19 is turned off. The twentieth transistor M20 is turned on, the seventh voltage signal V7 (high-level signal VGH) is transmitted to the fifth node N5 through the twentieth transistor M20, so that the fifth node N5 is at a high level, and the eleventh transistor M11 is turned off. The twenty-first transistor M21 and the twenty-second transistor M22 are turned on, and a signal from the twelfth node N12 is transmitted to the sixth node N6, so that the sixth node N6 is at a low level. The twelfth transistor M12 is turned on, and the sixth node N6 is turned on. The voltage signal V6 (low-level signal VGL) is transmitted to an output terminal, so that the first output signal SN_NEXT is at a low level.

Since the fourth module 2124 in the second control part 20 obtained by copying the twenty-first transistor M21, the twenty-second transistor M22, the twenty-third transistor M23 and the sixth capacitor C6, the third node N3 output by the fourth module 2124 is essentially a synchronization signal with the sixth node N6. Therefore, in the above Ta-Td stages, both the sixth node N6 and the third node N3 are high-level signals. In the Te stage, the sixth node N6 and the third node N3 are switched to low-level signals. The third transistor M3 is turned off in the Ta-Td stages but is turned on in the Te stage and outputs the second voltage signal V2 (the low-level signal VGL), and the second output signal SN_OUT is a low-level signal in the Te stage.

As shown in FIGS. 16-20, each transistor in the first control part 10 is a PMOS transistor. A person skilled in the art can also change a type of a transistor according to actual needs, such as using an NMOS transistor, which is not limited herein. Moreover, circuit structures of the first control part 10, as shown in FIGS. 16-20, are only part of the embodiments. A person skilled in the art can also replace the first control part with other circuit structures according to actual needs. The modifications do not affect a core solution of the present disclosure, and any reasonable modifications made based on the embodiments shown in the present disclosure also fall within the protection scope of the present disclosure.

In one embodiment, a pixel circuit is provided. FIGS. 22-26 illustrate schematic diagrams of five other pixel circuits consistent with various embodiments of the present disclosure. Referring to FIGS. 3 and 22-26, in one embodiment, the display panel further includes a pixel circuit 200, where the second output signal SN_OUT from the drive circuit 100 serves as a control signal for a preset module in the pixel circuit 200. When the second output signal SN_OUT is an invalid pulse, the preset module is turned on, and when the second output signal SN_OUT is an invalid pulse, the preset module is turned off.

A process of driving the preset modules in the pixel circuit 200 by the driving circuit 100 of the present disclosure will be introduced below with reference to pixel circuits shown in FIG. 3 and FIGS. 22-26. A person skilled in the art will know that each pixel circuit 200 shown in FIG. 3 and FIGS. 22-26 may include a data writing module 210, a driving module 220, a threshold compensation module 230, a gate reset module 250, an initialization module 260, a lighting module control module 270. The driving module 220 includes a driving transistor T2, which is configured to supply a driving current to light-emitting elements 300 of the display panel 100. The data writing module 210 is connected to a first electrode (i.e., the N2 node) of the driving transistor T2, and is configured to provide a data signal to the driving transistor T2. The threshold compensation module 230 is connected between a gate (i.e., the N1 node) of the driving transistor T2 and a second electrode (i.e., the N3 node) of the driving transistor T2, and is configured to compensate a threshold voltage of the driving transistor T2. The gate reset module 250 is configured to provide a reset signal Vref to a gate of the driving transistor T2. The initialization module 260 is configured to provide an initialization signal Vini to the light-emitting element 300. The light-emitting control module 270 is configured to selectively allow a light-emitting element 300 to enter a light-emitting stage. Optionally, the light emission control module 270 includes a first light emission control module 271 and a second light emission control module 272. The first light emission control module 271 is connected between a first power signal terminal and one electrode of the driving transistor T2, while the second light emission control module 272 is connected between the other electrode of the driving transistor T2 and a light emitting element 300.

A control terminal of the data writing module 210 receives a first scan signal S1, and the first scan signal S1, which controls an opening and closing of the data writing module 210. A control terminal of the threshold compensation module 230 receives a second scan signal S2, which controls an opening and closing of the threshold compensation module 230. A control terminal of the gate reset module 250 receives a third scan signal S3, which controls turning on and off of the gate reset module 250. A control terminal of the initialization module 260 receives the fourth scan signal S4, which controls turning on and off of the initialization module 260. A control terminal of the lighting control module 270 receives the lighting control signal EM, which controls turning on and off of the lighting control module 270.

The data writing module 210 includes a data writing transistor T1, and the first scan signal S1 controls turning on and off of the data writing transistor T1. The threshold compensation module 230 includes a compensation transistor T3, and the second scan signal S2 controls turning on and off of the compensation transistor T3. The gate reset module 250 includes a reset transistor T5, and the third scan signal S3 controls turning on and off of the reset transistor T5. The initialization module 260 includes an initialization transistor T6, and the fourth scan signal S4 controls turning on and off of the initialization transistor T6. The first lighting control module 271 includes a first lighting control transistor T7, and the second lighting control module 272 includes a second lighting control transistor T8. The light-emitting control signal EM controls turning on and off of the first light-emitting control transistor T7 and the second light-emitting control transistor T8.

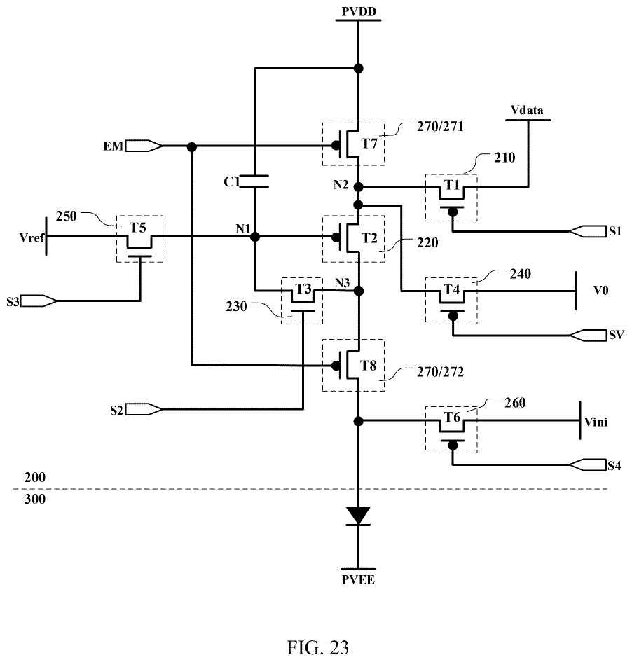

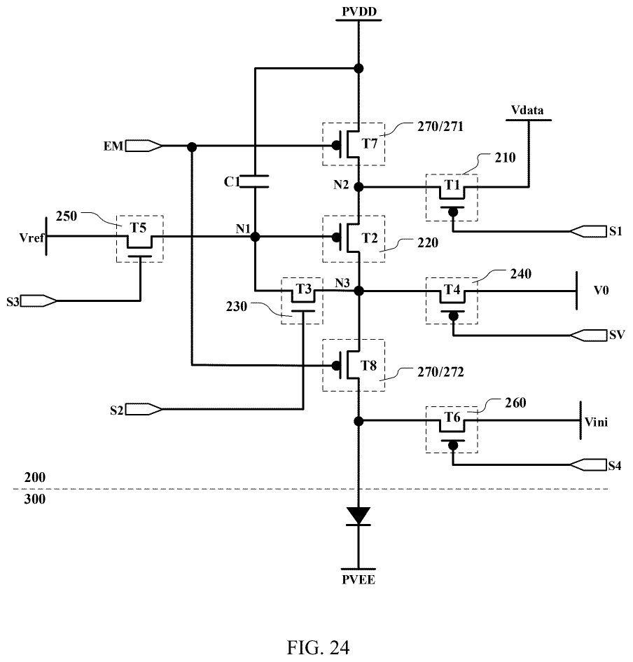

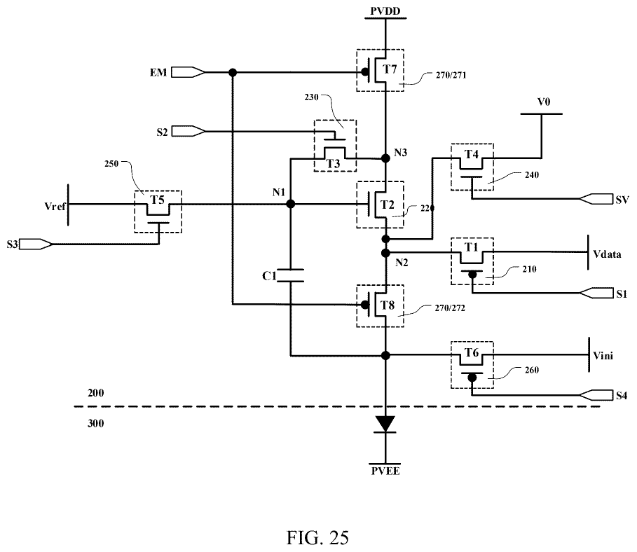

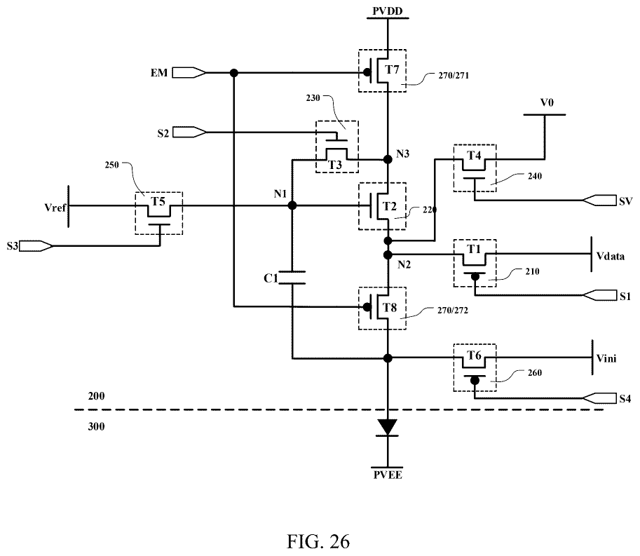

As shown in FIGS. 23-26, the pixel circuit may further include a bias adjustment module 240, which provides a bias adjustment signal to the driving transistor T2. Optionally, in FIGS. 23 and 25, the bias adjustment module 240 is connected to a first electrode (i.e., the N2 node) of the driving transistor T2. In FIGS. 24 and 26, the bias adjustment module 240 is connected to a second electrode (i.e., the N3 node) of the driving transistor T2. Optionally, a control terminal of the bias adjustment module 240 receives a bias adjustment control signal SV, which controls turning on and off of the bias adjustment module 240. The bias adjustment module 240 includes a bias adjustment transistor T4, the bias adjustment control signal SV controls turning on and off of the bias adjustment transistor T4.

In the pixel circuits shown in FIGS. 3, 23, and 25, the driving transistor T2 is a PMOS transistor. A pixel circuit further includes a storage capacitor C1. A first electrode of the storage capacitor C1 is connected to the first power signal terminal, and a second electrode of the storage capacitor C1 is connected to the gate of the driving transistor T2 for storing signals transmitted to the gate of the driving transistor T2. In the pixel circuits shown in FIGS. 22, 24, and 26, the driving transistor T2 is an NMOS transistor. A pixel circuit further includes the storage capacitor C1. The first electrode of the storage capacitor C1 is connected to the light-emitting element 300 and the second electrode of the storage capacitor C1 is connected to the gate of the driving transistor T2 for storing signals transmitted to the gate of the driving transistor T2.

In one embodiment, the pixel circuit receives power signals PVDD and PVEE and generates a driving current through a voltage difference between the power signals PVDD and PVEE, thereby driving a light-emitting element to emit light. The PVDD signal may be a positive power signal, and the PVEE signal may be a negative power signal.

FIG. 3 and FIGS. 22 to 26 only provide embodiments of structures of several pixel circuits, but do not include all of pixel circuits. Other pixel circuits with power signals PVDD and PVEE that meet limitations of the present disclosure fall within the protection scope of the embodiments of the present disclosure.

Based on the above various types of pixel circuits, in one embodiment, the driving circuit 100 can provide corresponding control signals to the threshold compensation module 230 or the gate reset module 250. That is, the preset module in the above pixel circuit 200 can be either the threshold compensation module 230 or the gate reset module 250. The second output signal SN_OUT of the driving circuit 100 may serve as a control signal for the threshold compensation module 230 or the gate reset module 250.

As an example, when the second output signal SN_OUT of the driving circuit 100 is used as a control signal for the threshold compensation module 230, the preset module is the threshold compensation module 230. Referring to FIG. 3 and FIGS. 22-26, Optionally, the preset module includes N-type channel transistors, and the second output signal SN_OUT is a control signal of the N-type channel transistors. When the second output signal SN_OUT is a high-level signal and in the valid pulse stage, the N-channel transistors are controlled to turn on. In other embodiments, optionally, the preset module includes P-type channel transistors, and the second output signal SN_OUT serves as a control signal for the P-type channel transistors. When the second output signal SN_OUT is a low-level signal and in the valid pulse stage, the P-channel transistors are controlled to turn on.

As an example, when the second output signal SN_OUT of the driving circuit 100 serves as a control signal for the threshold compensation module 230, the threshold compensation module 230 functions as the preset module. The threshold compensation module 230 includes N-channel transistors. A driving principle of the pixel circuit 200 is described below.

Referring to FIG. 10, the shift registers 110 at different stages generally provide driving signals to the pixel circuits 200 in different rows, specifically supplying data writing control signals to the data writing modules 210 of the pixel circuits 200 in different rows. Taking any level shift register as an example, as described above, in the second stage t2 and the third stage t3, the second output signal SN_OUT is a valid pulse, that is, a high-level signal. A gate of the N-channel transistor T3 in the threshold compensation module 230 receives the high-level signal and is turned on, and the threshold compensation module 230 is in a turning-on state. Therefore, when the pixel circuit 200 is in the pixel writing stage, meaning the data writing module 210 is turned on synchronously, the pixel circuit 200 begins to write data signals, and the storage capacitor C1 starts to charge. When the pixel circuit 200 is in the light-emitting stage, the first light-emitting control module 271 and the second light-emitting control module 272 are turned on, the storage capacitor C1 begins to discharge, and the driving transistor T2 is controlled by the voltage at the first node N1 to emit light. In the third stage t3, since the second terminal of the first capacitor C1 in the driving circuit 100 is electrically insulated from the first voltage input terminal 2101, the second output signal SN_OUT will not be affected, ensuring that a data signal is normally written to the first node N1 of the pixel circuit 200 in the data writing stage, so that the light-emitting element can be controlled to emit light according to the target brightness in the light-emitting stage, thereby solving the issue of dark or bright lines at junctions of different partitions in display panels with a partition frequency adjustment function, which can result in abnormal displays.

In the zeroth stage t0, the first stage t1, the fourth stage t4 and the fifth stage t5, the second output signal SN_OUT is an invalid pulse, that is, a low-level signal. The gate of the N-channel transistor T3 in the threshold compensation module 230 receives the low-level signal and turns off, placing the threshold compensation module 230 in a turning-off state. Therefore, even if the pixel circuit 200 is in the data writing stage, that is, when the data writing module 210 is turned on synchronously, the pixel circuit 200 cannot write the data signal to the first node N1 and cannot affect an actual data writing process of the pixel circuit 200. Even in the zeroth stage t0, an invalid pulse of the second output signal SN_OUT is influenced by a level transition of the frequency control signal SN_Ctrl in the driving circuit 100 and generates ripples. The ripples will not affect the data writing of the pixel circuit 200 and can still ensure that the pixel circuit 200 normally writes the data signal and controls the light-emitting element to emit light according to the target brightness in the light-emitting stage, thereby solving the issue of dark or bright lines at junctions of different partitions in display panels with a partition frequency adjustment function, which can result in abnormal displays.

A person skilled in the art understands that an opening process of the gate reset module 250 in the pixel circuit 200 during each data refresh cycle also directly affects whether the pixel circuit 200 can drive a corresponding light-emitting element 300 to emit light. In other words, when the gate reset module 250 uses the second output signal SN_OUT as a control signal, the shift register 110 can also determine whether the corresponding light-emitting element 300 emits light normally. Specific functions of each module can be deduced by a person skilled in the art, which are not detailed herein.

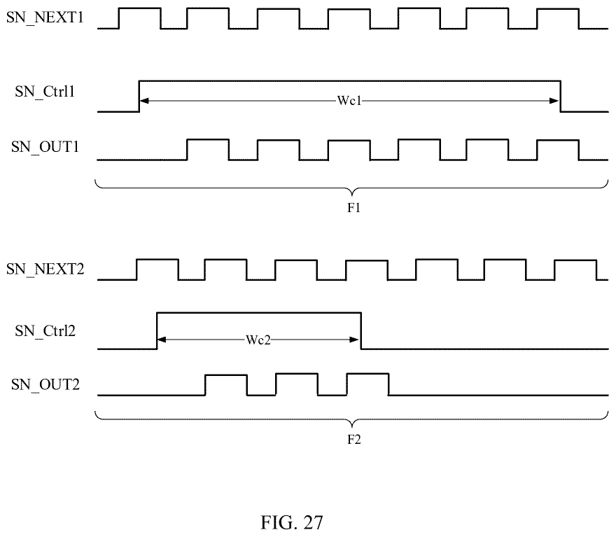

FIG. 27 illustrates a driving timing diagram of the display panel shown in FIG. 7. Referring to FIGS. 7 and 27, in one embodiment, the display panel may include a first display area AA1 and a second display area AA2. The first display area AA1 includes a first pixel circuit 201, and the second display area AA2 includes a second pixel circuit 202. The driving circuit 100 consists of a first shift register 111 and a second shift register 112. The preset module in the first pixel circuit 201 is designated as a first preset module, and the preset module in the second pixel circuit 202 is referred to as a second preset module. A first output signal SN_OUT from the first shift register 111 serves as a control signal for the first preset module, while a second output signal SN_OUT2 from the second shift register 112 acts as a control signal for the second preset module. A pulse variation frequency of the first output signal SN_OUT1 received by the first preset module is F1, and a pulse variation frequency of the second output signal SN_OUT2 received by the second preset module is F2, where F1>F2.

Referring to FIG. 10, in the shift register 110, the frequency control signal SN_Ctrl directly determines an output of a valid pulse of the output signal SN_OUT. Therefore, for different areas of the display panel, by providing different frequency control signals SN_Ctrl to corresponding shift registers 110, the output signals SN_OUT from the shift registers 110 received by different partitions of the display panel have different numbers of valid pulses, that is, different pulse variation frequencies. As shown in FIGS. 7, 10, and 27, by providing a first frequency control signal SN_Ctrl1 to the first shift register 111 corresponding to the first display area AA1, and a second frequency control signal SN_Ctrl2 to the second shift register 112 corresponding to the second display area AA2, and by reasonably setting a valid pulse duration Wc1 of the first frequency control signal SN_Ctrl1 to be greater than a valid pulse duration Wc2 of the second frequency control signal SN_Ctrl2, number of valid pulses in the first output signal SN_OUT1 from the first shift register 111 can exceed number of valid pulses in the second output signal SN_OUT2 from the second shift register 112. That is, the pulse variation frequency F1 of the first output signal SN_OUT1 from the first shift register 111 is greater than the pulse variation frequency F2 of the second output signal SN_OUT2 from the second shift register 112.

As shown in FIG. 27, changing a valid pulse duration Wc of the frequency control signal SN_Ctrl to adjust a pulse variation frequency of the output signal SN_OUT from the shift register 110 received by different partitions is only one embodiment. In other embodiments, a pulse variation frequency of the frequency control signal SN_Ctrl can also be changed, or a same frequency control signal SN_Ctrl can be used, so that the pulse variation frequency of the output signal SN_OUT from the shift register 110 received by different partitions varies.

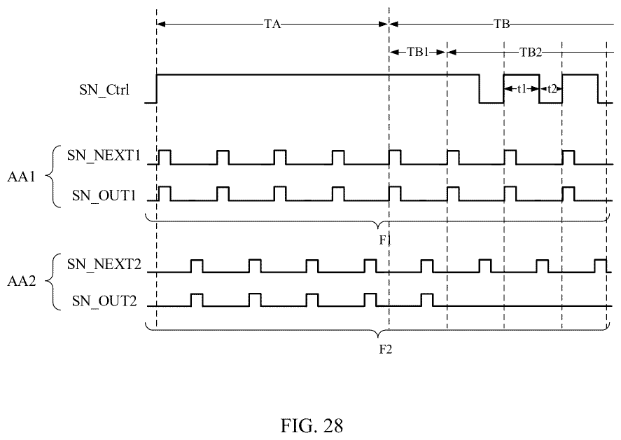

FIG. 28 illustrates another driving timing diagram of the display panel shown in FIG. 7. Referring to FIGS. 7 and 28, optionally, the frequency control signal SN_Crtl1 received by the first shift register 111 is same as the frequency control signal SN_Crtl2 received by the second shift register 112.

Since different shift registers 110 are cascaded with each other, the first output signal SN_NEXT from the first control unit 10 in the shift register 110 at each stage serves as an input signal for the first control unit 10 in a next lower stage. Therefore, the first output signal SN_NEXT from the first control unit 10 of the shift registers 110 at each stage is sequentially shifted in time. As shown in FIG. 28, there is a timing misalignment between valid pulses of the first output signal SN_NEXT1 of the first shift register 111 and valid pulses of the first output signal SN_NEXT2 of the second shift register 112. Therefore, in one embodiment, by reasonably setting the pulse width, frequency and timing of the valid pulse of the frequency control signal SN_Ctrl, a same frequency control signal SN_Ctrl can be used to control the first shift register 111 corresponding to the first display area AA1 and the first shift register 112 corresponding to the second display area AA2 to output different numbers of valid pulses. In other words, in the embodiment, according to the working principle that the frequency control signal SN_Ctrl and the first output signal SN_NEXT are jointly controlled by the driving circuit 100 to control the output signal SN_OUT, and under a condition that the frequency control signal SN_Ctrl remains same, shifting conditions of the first output signal SN_NEXT corresponding to different display areas can create different overlapping states between valid pulses of the first output signal SN_NEXT and the frequency control signal SN_Ctrl. Therefore, the output signal SN_OUT produces different numbers of valid pulses, and the first output signal SN_OUT1 received by the first display area AA1 and the second output signal SN_OUT2 received by the second display area AA2 have different pulse change frequencies, resulting in different refresh frequencies in the first display area AA1 and the second display area AA2.

Referring to FIGS. 7 and 28, optionally, the display process of the display panel includes a first stage TA and a second stage TB. The second stage TB includes a first sub-stage TB1 and a second sub-stage TB2. In the first stage TA and the first sub-stage TB1, a level of the frequency control signal SN_Ctrl received by the first shift register 111 and a level of the frequency control signal SN_Ctrl received by the second shift register 112 are both a first level. The first output signal SN_OUT1 received by the first preset module and the second output signal SN_OUT2 received by the second preset module both includes a valid pulse. In the second sub-stage TB2, the level of the frequency control signal SN_Ctrl received by the first shift register 111 is the first level, the first output signal SN_OUT1 received by the first preset module includes a valid pulse, and level of the frequency control signal SN_Ctrl received by the second shift register 112 is the second level, and the second output signal SN_OUT2 received by the second preset module includes an invalid pulse.

In the first stage TA, the frequency control signal SN_Ctrl received by the first shift register 111 and the frequency control signal SN_Ctrl received by the second shift register 112 are at a same level state, both being the first level, the frequency control signal SN_Ctrl shown in the FIG. 28 is at a high level, so the first display area AA1 driven by the first shift register 111 and the second display area AA2 driven by the second shift register 112 have a same operational state, that is, a same refresh frequency. The first stage TA can be understood as a first operating mode of the display panel, that is, a high-frequency refresh mode. In the high-frequency refresh mode, pixel circuits 200 in the first display area AA1 and the second display area AA2 complete a full driving display process in each frame, writing a new data signal in every frame, resulting in the display panels showing a new image.

A level state of the frequency control signal SN_Ctrl in the first sub-stage TB1 of the second stage TB is the same as a level state of the frequency control signal SN_Ctrl of the first stage T1, which is also the first level. The first display area AA1 driven by the first shift register 111 and the second display area AA2 driven by the second shift register 112 has a same operational state.

In the second sub-stage TB2 of the second stage TB, the level of the frequency control signal SN_Ctrl received by the first shift register 111 in the t1 stage, as shown in FIG. 28, is at the first level. The second output signal SN_OUT1 received by the first preset module includes a valid pulse, indicating that in the first sub-phase TB1, the first output signal SN_NEXT1 from the first control part 10 in the first shift register 111 has valid pulses. Since the frequency control signal SN_Ctrl is at the first level, which is the invalid pulse stage, the second control part 20 can output valid pulses. That is, in the t1 stage, the second output signal SN_OUT1 provided by the first shift register 111 to the first preset module has valid pluses. The level of the frequency control signal SN_Ctrl received by the second shift register 112 in the t2 stage, as shown in FIG. 28, is the second level. The second output signal SN_OUT2 received by the second preset module contains invalid pulses, indicating that in the t2 stage, the first output signal SN_NEXT1 from the first control part 10 in the second shift register 112 contains valid pulses. However, because the frequency control signal SN_Ctrl is at the second level, which is the invalid pulse stage, the second control unit 20 outputs invalid pulses. That is, in the second sub-stage TB2, the second output signal SN_OUT2 from the second shift register 112 provided to the second preset module contains invalid pulses.

Therefore, the second stage TB can be understood as a second operating mode of the display panel, that is, a low-power refresh mode. In the first display area AA1, the pixel circuit 200 can effectively write a new data signal in both the first sub-stage TB1 and the second sub-stage TB2, allowing the first display area AA1 to display a new image. In other words, in the second stage TA, the first display area AA1 remains in a high-frequency refresh display state, like the first stage TA. For the second display area AA2, the first sub-stage TB1 can be understood as a refresh frame, while the second sub-stage TB2 represents a series of holding frames (in other possible implementations, the second sub-stage TB2 may include only include one holding frame). The pixel circuit 200 writes a new data signal in the first sub-stage TB1, which is the refresh frame. The second display area AA2 also displays a new image, but in the second sub-stage TB2, which is a holding frame. The pixel circuit 200 does not receive a new data signal and uses a data signal for the refresh frame to maintain a light-emitting state of the light-emitting element 300. The second display area AA2 retains the image for display using the refresh frame.

In one embodiment, assuming that the display panel is scanned from top to bottom, the first display area AA1 is a high-frequency display area, and the second display area AA2 is a low-frequency display area. The first display area AA1 can be located either above or below the second display area AA2, which is not limited herein. If the first display area AA1 is located above the second display area AA2, the pixel circuits in the first display area AA1 scans before the pixel circuits in the second display area AA2. In the second sub-stage TB2, the frequency control signal SN_Ctrl starts as a first level signal, and changes to a second level signal to correspond to the two display areas respectively. On the contrary, if the first display area AA1 is located below the second display area AA2, the pixel circuits in the first display area AA1 scans later than the pixel circuits in the second display area AA2. In the second sub-stage TB2, the frequency control signal SN_Ctrl starts as a second level signal and changes to a first level signal to correspond to the two display areas respectively.

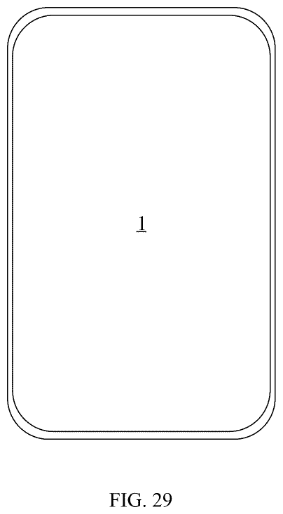

Based on a same inventive concept, embodiments of the present disclosure also provide a display device. FIG. 29 illustrates a schematic diagram of a display device consistent with various embodiments of the present disclosure. Referring to FIG. 29, the display device includes a display panel provided by any embodiment of the present disclosure. Therefore, the display device has corresponding beneficial effects of the display panel provided by the embodiment of the present disclosure, which will not be described again herein. For example, the display device may be an electronic device such as a mobile phone, a computer, a smart wearable device (for example, a smart watch), a vehicle-mounted display device, or the like.

As disclosed, the display panel and the display device provided by the present disclosure at least realize the following beneficial effects.

The technical solution of the embodiments of the present disclosure is to provide the first control part and the second control part in the shift register. The first control part is configured to control the first output signal, so that the first output signal of the i-th level shift register serves as the input signal of the j-th level shift register, enabling a cascade connection of at least two levels of the first control part. The control unit is configured to receive at least the frequency control signal, the first voltage signal input from the first voltage input terminal and the second voltage signal input from the second voltage input terminal and control the second output signal so that a voltage corresponding to a valid pulse of the second output signal is same as the voltage of the first voltage signal. The voltage corresponding to the invalid pulse of the second output signal is the same as the voltage of the second voltage signal. The frequency control signal can be used to realize a conversion of a valid pulse and an invalid pulse of the second output signal, thereby controlling the pixel circuit and realizing an adjustment of refresh frequencies in different areas of the display panel. In addition, the first terminal of the first voltage stabilizing unit is electrically connected to the control unit, while the second terminal of the first voltage stabilizing unit receives a fixed voltage signal and is connected to a different voltage signal line than the first voltage input terminal. The first voltage stabilizing unit can stabilize a voltage of a node connected to the first voltage stabilizing unit in the control unit, maintain an operational state of the control unit, and prevent the second output signal for the control unit from being cut off in the valid pulse stage, ensuring an output of a complete valid pulse. At a same time, the second terminal of the first voltage stabilizing unit avoids interfering with the first voltage signal from the first voltage input terminal, thereby preventing fluctuations in the second output signal during an output of valid pulses, which may affect the operational state of the pixel circuit. As a result, the pixel circuit ensures that the light-emitting element corresponding to the pixel circuit can emit light according to the target brightness, avoiding display issues such as bright or dark lines on the display panel and ensuring display quality.

The above are only preferred embodiments of the present disclosure and the technical principles employed. A person skilled in the art will understand that the present disclosure is not limited to the specific embodiments described herein. Various obvious changes, readjustments, combinations and substitutions may be made by a person skilled in the art without departing from the protection scope of the present disclosure. Therefore, although the present disclosure has been described in detail through the above embodiments, the present disclosure is not limited to the above embodiments and may encompass other equivalent embodiments without departing from concepts of the present disclosure. The protection scope of the present disclosure is determined by the protection scope of the appended claims.

What is claimed is:

1. A display panel, comprising a driving circuit includes N-level shift registers connected in cascade with N≥2, wherein:
a shift register of the N-level shift registers includes a first control part and a second control part, the first control part is electrically connected to the second control part;
the first control part is configured to control a first output signal, and the first output signal of an i-th level shift register serves as an input signal of a j-th level shift register, 1≤i≤N, and 1≤j≤N;
the second control part includes a control unit and a first voltage stabilizing unit;
the control unit at least receives a frequency control signal, a first voltage signal input from a first voltage input terminal and a second voltage signal input from a second voltage input terminal, and controls a second output signal;
a voltage corresponding to a valid pulse of the second output signal is same as a voltage of the first voltage signal, a voltage corresponding to an invalid pulse of the second output signal is same as a voltage of the second voltage signal;
a first terminal of the first voltage stabilizing unit is electrically connected to the control unit, and a second terminal of the first voltage stabilizing unit receives a fixed voltage signal; and
a voltage signal line connected to the second terminal of the first voltage stabilizing unit is different from a voltage signal line connected to the first voltage input terminal.

2. The display panel according to claim 1, wherein the second terminal of the first voltage stabilizing unit is electrically connected to the second voltage input terminal.

3. The display panel according to claim 1, wherein the second terminal of the first voltage stabilizing unit is electrically insulated from the second voltage input terminal.

4. The display panel according to claim 3, comprising a fixed voltage signal line electrically connected to the second terminal of the first voltage stabilizing unit in the shift register.

5. The display panel according to claim 4, wherein:
one of the first voltage signal and the second voltage signal is a high-level signal, and the other of the first voltage signal and the second voltage signal is a low-level signal;
a voltage V0 of the fixed voltage signal satisfies: VGL≤V0≤VGH; and
VGH is a voltage value of the high-level signal among the first voltage signal and the second voltage signal, and VGL is a voltage value of the low-level signal among the first voltage signal and the second voltage signal.

6. The display panel according to claim 1, wherein:
the control unit includes a first control unit and a second control unit;
the first control unit receives at least the first output signal and the frequency control signal, and controls a signal from a first node;
the first terminal of the first voltage stabilizing unit is electrically connected to the first node; and
the second control unit receives at least one signal from the first node, the first voltage signal from the first voltage input terminal and the second voltage signal from the second voltage input terminal and controls the second output signal.

7. The display panel according to claim 6, wherein:
the second control unit includes a first module, a second module and a third module;
the first module receives the first output signal, a signal from the first node and a third voltage signal from a third voltage input terminal, and controls a signal from a second node;
the second module receives the first output signal, a signal from the first node and a fourth voltage signal from a fourth voltage input terminal, and controls a signal from the second node;
the third module receives the first voltage signal from the first voltage input terminal and the second voltage signal from the second voltage input terminal, and at least one signal from the second node, and outputs the second output signal; and
one of the third voltage signal and the fourth voltage signal is a high-level signal, and the other of the third voltage signal and the fourth voltage signal is a low-level signal.

8. The display panel according to claim 7, wherein:
one of the first voltage signal and the second voltage signal is the high-level signal, and the other of the first voltage signal and the second voltage signal is the low-level signal;
the high-level signal from the first voltage signal and the second voltage signal and the high-level signal from the third voltage signal and the fourth voltage signal are signals with different voltages;
the low-level signal from the first voltage signal and the second voltage signal and the low-level signal from the third voltage signal and the fourth voltage signal are signals of different voltages; and
the second terminal of the first voltage stabilizing unit is electrically connected to the third voltage input terminal or the fourth voltage input terminal.

9. The display panel according to claim 8, wherein:
a voltage value of the high-level signal from the first voltage signal and the second voltage signal is VGH1, and a voltage value of the high-level signal from the third voltage signal and the fourth voltage signal is VGH2, with VGH1>VGH2; and/or
a voltage value of the low-level signal from the first voltage signal and the second voltage signal is VGL1, and a voltage value of the low-level signal from the third voltage signal and the fourth voltage signal is VGL2, with VGL1<VGL2.

10. The display panel according to claim 7, wherein:
the high-level signal from the first voltage signal and the second voltage signal and the high-level signal from the third voltage signal and the fourth voltage signal are signals with a same voltage; and
the low-level signal from the first voltage signal and the second voltage signal and the low-level signal from the third voltage signal and the fourth voltage signal are signals with a same voltage.

11. The display panel according to claim 7, wherein:
the third module includes a second transistor and a third transistor, which have different channel types;
a first electrode of the second transistor receives the first voltage signal, a second electrode of the second transistor is used to output the second output signal, and a gate of the second transistor is electrically connected to the second node; and
a first electrode of the third transistor receives the second voltage signal, a second electrode of the third transistor is used to output the second output signal, and a gate of the third transistor is electrically connected to the second node.

12. The display panel according to claim 7, wherein:
the third module includes a second transistor and a third transistor, which have a same channel type;
a first electrode of the second transistor receives the first voltage signal, a second electrode of the second transistor is used to output the second output signal, and a gate of the second transistor is electrically connected to the second node; and
a first electrode of the third transistor receives the second voltage signal, a second electrode of the third transistor is used to output the second output signal, a gate of the third transistor is electrically connected to the third node and the third node is an electrical connection node in the first control part.

13. The display panel according to claim 11, wherein:
the second control unit also includes a second voltage stabilizing unit; and
a first terminal of the second voltage stabilizing unit is electrically connected to a gate of the third transistor, a second terminal of the second voltage stabilizing unit is electrically connected to a second electrode of the third transistor.

14. The display panel according to claim 7, wherein:
the first module includes a fourth transistor and a fifth transistor;
a first electrode of the fourth transistor receives the third voltage signal, a second electrode of the fourth transistor is electrically connected to the fourth node, and a gate electrode of the fourth transistor receives the first output signal; and
a first electrode of the fifth transistor is electrically connected to the fourth node, a second electrode of the fifth transistor is electrically connected to the second node, and a gate electrode of the fifth transistor is electrically connected to the first node.

15. The display panel according to claim 7, wherein:
the second module includes a sixth transistor and a seventh transistor;
a first electrode of the sixth transistor receives the fourth voltage signal, a second electrode of the sixth transistor is electrically connected to the second node, and a gate electrode of the sixth transistor receives the first output signal; and
a first electrode of the seventh transistor receives the fourth voltage signal, a second electrode of the seventh transistor is electrically connected to the second node, and a gate electrode of the seventh transistor is electrically connected to the first node.

16. The display panel according to claim 6, wherein:
the first control unit includes a first transistor, a gate of the first transistor receives the first output signal, a first electrode of the first transistor receives the frequency control signal, and a second electrode of the first transistor is electrically connected to the first node.

17. The display panel according to claim 16, wherein:
the first transistor is a P-channel transistor, an invalid pulse of the first output signal is a low-level signal, and a valid pulse of the first output signal is a high-level signal; or
the first transistor is an N-channel transistor, an invalid pulse of the first output signal is a high-level signal, and a valid pulse of the first output signal is a low-level signal.

18. The display panel according to claim 1, wherein the first voltage stabilizing unit includes at least one capacitor.

19. The display panel according to claim 1, comprising a pixel circuit, with the second output signal of the driving circuit serving as a control signal for a preset module of the pixel circuit, wherein:
the preset module is turned on when the second output signal is in a valid pulse stage;
the preset module is turned off when the second output signal is in an invalid pulse stage;
the display panel further includes a first display area and a second display area:
the first display area includes a first pixel circuit, and the second display area includes a second pixel circuit;
the driving circuit includes a first shift register and a second shift register;
the preset module in the first pixel circuit is a first preset module, the preset module in the second pixel circuit is a second preset module, the second output signal output by the first shift register is a control signal for the first preset module, and the second output signal output by the second shift register is a control signal for the second preset module; and
a pulse variation frequency of the second output signal received by the first preset module is F1, while a pulse variation frequency of the second output signal received by the second preset module is F2, with F1>F2.

20. A display device comprising a display panel, comprising a driving circuit includes N-level shift registers connected in cascade with N≥2, wherein:
a shift register of the N-level shift registers includes a first control part and a second control part, the first control part is electrically connected to the second control part;
the first control part is configured to control a first output signal, and the first output signal of an i-th level shift register serves as an input signal of a j-th level shift register, 1≤i≤N, and 1≤j≤N;
the second control part includes a control unit and a first voltage stabilizing unit;
the control unit at least receives a frequency control signal, a first voltage signal input from a first voltage input terminal and a second voltage signal input from a second voltage input terminal, and controls a second output signal;
a voltage corresponding to a valid pulse of the second output signal is same as a voltage of the first voltage signal, a voltage corresponding to an invalid pulses of the second output signal is same as a voltage of the second voltage signal;
a first terminal of the first voltage stabilizing unit is electrically connected to the control unit, and a second terminal of the first voltage stabilizing unit receives a fixed voltage signal; and
a voltage signal line connected to the second terminal of the first voltage stabilizing unit is different from a voltage signal line connected to the first voltage input terminal.
